(19) United States
(12) Patent Application Publication
(10) Pub. No.: US 2025/0157942 A1
(43) Pub. Date: May 15, 2025

(54) SEMICONDUCTOR DEVICE

(71) Applicant: Samsung Electronics Co., Ltd., Suwon-si (KR)

(72) Inventors: Jisoo Park, Suwon-si (KR); Jung Han Lee, Suwon-si (KR)

(21) Appl. No.: 18/647,135

(22) Filed: Apr. 26, 2024

(30) Foreign Application Priority Data
Nov. 9, 2023 (KR) 10-2023-0154467

(51) Int. Cl. H01L 23/544; H01L 29/08; H01L 29/66; H01L 29/775

(52) U.S. Cl. CPC H01L 23/544; H10D 62/151; H01L 2223/54426; H10D 30/014; H10D 30/43

(57) ABSTRACT

A semiconductor device includes a substrate including a logic cell region including active patterns spaced apart in a first direction and extending in a second direction different from the first direction, and an overlay key region including a back-side key pattern and a front-side key pattern, source/drain patterns on the active patterns of the logic cell region and spaced apart in the second direction, a channel pattern between the source/drain patterns, and a gate pattern extending in the first direction, crossing between the source/drain patterns, and surrounding at least a part of the channel pattern, wherein the substrate has an upper surface and a lower surface facing each other in a third direction different from the first direction and the second direction, and the back-side key pattern of the overlay key region extends into the lower surface of the substrate.

### CROSS-REFERENCE TO RELATED APPLICATION

This application claims priority to and the benefit of Korean Patent Application No. 10-2023-0154467 filed on Nov. 9, 2023, in the Korean Intellectual Property Office, the entire contents of which are incorporated herein by reference.

### BACKGROUND OF THE DISCLOSURE

### (a) Field of the Disclosure

The present disclosure relates to a semiconductor device, for example, a transistor including a nanowire or nanosheet, or a fin-type transistor including a channel pattern in the shape of a fin-type pattern.

### (b) Description of the Related Art

A semiconductor is a material that belongs to a middle region classification between a conductor and a nonconductor and refers to a material that conducts electricity under certain conditions. Various semiconductor devices, for example, a memory device, etc. may be manufactured using semiconductor materials. The semiconductor devices may be used in various electronic devices.

As the electronics industry is highly advanced, demands for the performance characteristics of semiconductor devices are increasing. For example, demands for high reliability, high speed, and/or multifunctionality for semiconductor devices are increasing. To meet these desired characteristics, structures within semiconductor devices are increasingly complex and integrated.

### SUMMARY OF THE DISCLOSURE

The present disclosure attempts to provide a semiconductor device that is more integrated and has a reduced alignment error between a lower contact located on the back-side and a source/drain pattern and a gate pattern located on the front-side by applying a back-side power distribution network (BSPDN) structure.

According to an aspect, a semiconductor device includes a substrate including a logic cell region including active patterns spaced apart in a first direction and extending in a second direction different from the first direction, and an overlay key region including a back-side key pattern and a front-side key pattern, source/drain patterns on the active patterns of the logic cell region and spaced apart in the second direction, a channel pattern between the source/drain patterns, and a gate pattern extending in the first direction, crossing between the source/drain patterns, and surrounding at least a part of the channel pattern, wherein the substrate has an upper surface and a lower surface facing each other in a third direction different from the first direction and the second direction, and the back-side key pattern of the overlay key region extends into the lower surface of the substrate.

According to another aspect, a semiconductor device includes a substrate including a logic cell region including active patterns spaced apart in a first direction and extending in a second direction different from the first direction, and an overlay key region including a front-side key pattern and a back-side key pattern, the substrate having an upper surface and a lower surface facing each other in a third direction different from the first direction and the second direction, source/drain patterns on the active patterns of the logic cell region and spaced apart in the second direction, a channel pattern located between the source/drain patterns, a gate pattern extending in the first direction, crossing between the source/drain patterns, and surrounding at least a part of the channel pattern, a lower active contact below the source/drain patterns in the third direction with the lower surface of the substrate being a base reference plane, extending into the active patterns, and electrically connected to the source/drain patterns, and a lower gate contact below the gate pattern in the third direction with the lower surface of the substrate being the base reference plane, extending into the active patterns, and electrically connected to the gate pattern, and a first lower interlayer insulating layer below the lower active contact and the lower gate contact in the third direction with the lower surface of the substrate being the base reference plane and including a first lower metal layer, wherein a lower surface of the back-side key pattern of the overlay key region contacts the first lower interlayer insulating layer.

According to another aspect, a semiconductor device includes a substrate including active patterns spaced apart in a first direction and extending in a second direction different from the first direction, a device isolation pattern between the active patterns in the first direction, and a back-side key pattern and a front-side key pattern on the device isolation pattern, and sacrificial layers and active layers on the active patterns and alternately stacked in a third direction different from the first direction and the second direction, wherein the back-side key pattern extends into a lower surface of the device isolation pattern, and wherein the front-side key pattern extends into an upper surface of the device isolation pattern, and is spaced apart from a lower surface of the substrate.

According to some embodiments, the semiconductor device may be more integrated and an alignment error between the lower contact located on the back-side and the source/drain patterns and the gate pattern located on the front may be reduced by applying a back-side power distribution network (BSPDN) structure.

### BRIEF DESCRIPTION OF THE DRAWINGS

FIG. 1 is a top plan view illustrating a semiconductor device according to some embodiments.

FIG. 2 is a top plan view illustrating a logic cell region of FIG. 1.

FIG. 3 is a cross-sectional view taken along line A-A′ of FIG. 2.

FIG. 4 is a cross-sectional view taken along line B-B′ of FIG. 2.

FIG. 5 is a cross-sectional view taken along line C-C′ of FIG. 2.

FIG. 6 is a cross-sectional view taken along line D-D′ of FIG. 2.

FIG. 7 is a cross-sectional view showing a second overlay key region of FIG. 1.

FIGS. 8 to 42 are cross-sectional views illustrating intermediate operations of a manufacturing method of the semiconductor device according to some embodiments.

### DETAILED DESCRIPTION OF THE EMBODIMENTS

Hereinafter, with reference to the accompanying drawings, various embodiments of the present disclosure will be described in detail so that those skilled in the art may easily carry out the present disclosure. Identical reference numerals are used for the same constituent elements in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. The present disclosure may be embodied in many different forms and is not limited to the embodiments set forth herein.

In addition, since the size and thickness of each component shown in the drawings are arbitrarily shown for convenience of description, the present disclosure is not limited to those shown. In the drawings, the thickness of layers, layers, panels, regions, etc., are exaggerated for clarity. In addition, in the drawings, for convenience of explanation, thicknesses of some layers and areas are exaggerated.

In addition, it will be understood that when an element such as a layer, layer, region, or substrate is referred to as being “on” another element, it may be directly on the other element or intervening elements may also be present. In contrast, when an element is referred to as being “directly on” another element, there are no intervening elements present. In addition, being “above” or “on” a reference part means being above or below the reference part, and does not necessarily mean being “above” or “on” in the opposite direction of gravity.

In addition, throughout the specification, unless explicitly described to the contrary, the word “comprise”, and variations such as “comprises” or “comprising”, will be understood to imply the inclusion of stated elements but not the exclusion of any other elements.

In addition, throughout the specification viewed “on a plane” or a plan view means when a target portion is viewed from above, and viewed “on a cross section” means when a cross section obtained by vertically cutting a target portion is viewed from the side.

In addition, throughout the specification, two directions parallel to an upper surface of a substrate and intersecting each other are defined as a first direction D1 and a second direction D2, respectively, and a direction perpendicular to the upper surface of the substrate is explained as a third direction D3. For example, the first direction D1 and the second direction D2 may be perpendicular to each other.

In addition, throughout the specification, a front surface or an upper portion may refer to a surface or a part located in a direction in which a front wiring unit is located (the positive third direction D3 in the drawing), and a back surface or a lower portion may refer to a surface or a part located in a direction in which a back wiring unit is located (the negative third direction D3 in the drawing).

In the drawing relating to a semiconductor device according to an embodiment, a transistor including a nanowire or a nanosheet, a multi-bridge channel field effect transistor (MBCFETTM™), and a fin-type transistor (FinFET) including a channel region in the shape of a fin-type pattern are illustrated as examples, but the present disclosure is not limited thereto. A semiconductor device according to some embodiments may include a tunneling FET, a 3D stack field effect transistor (3DSFET), or a complementary FET (CFET).

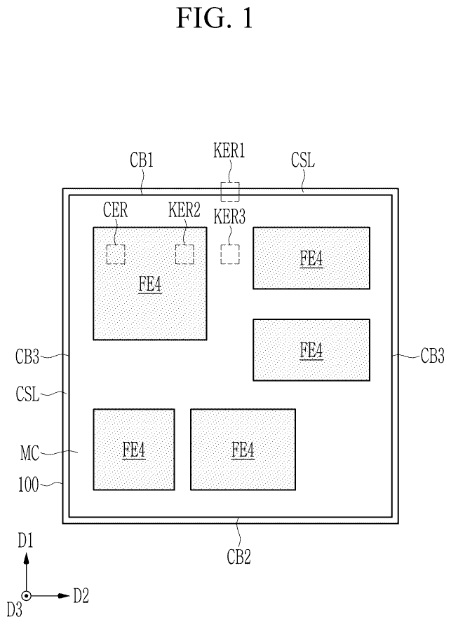

Hereinafter, a semiconductor device according to some embodiments will be described in detail with reference to FIGS. 1 to 7.

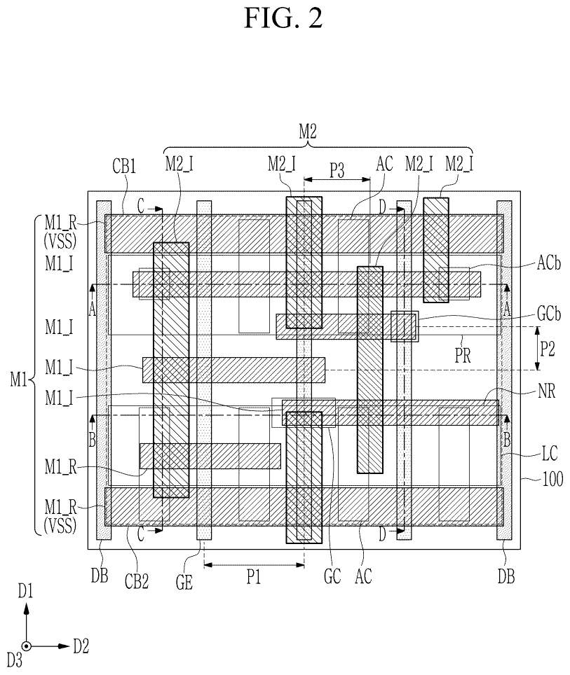

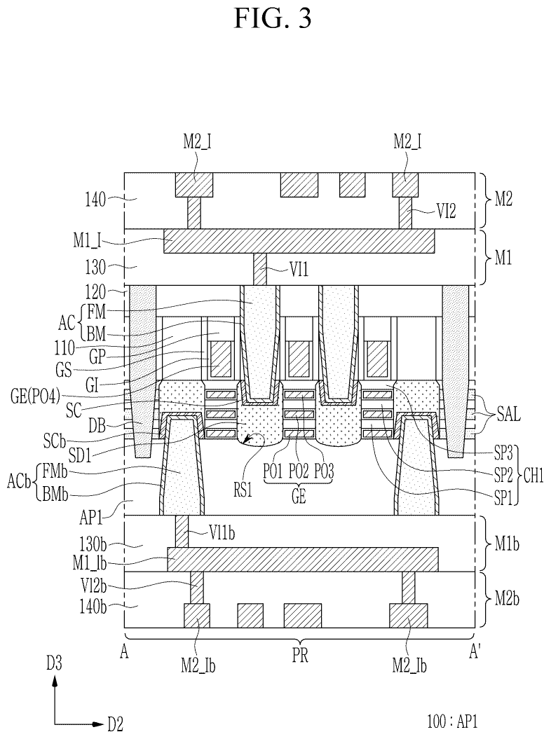

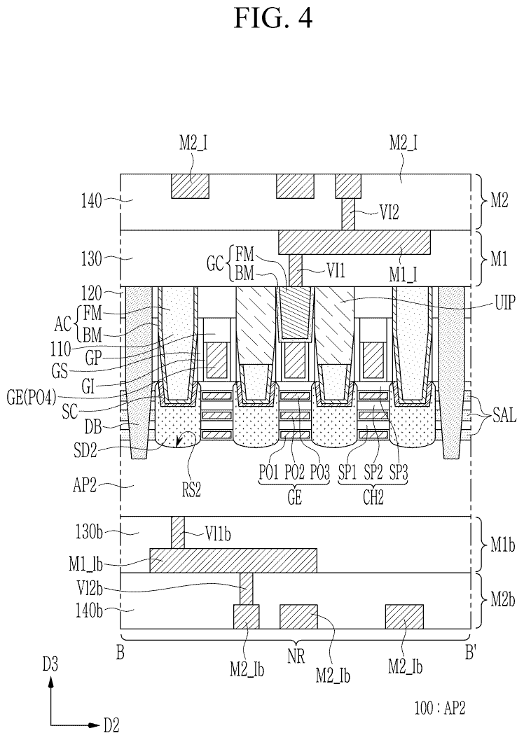

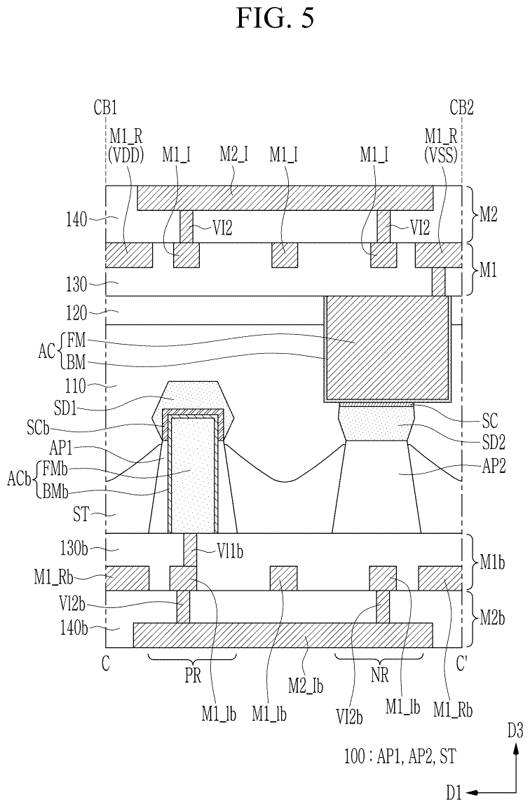

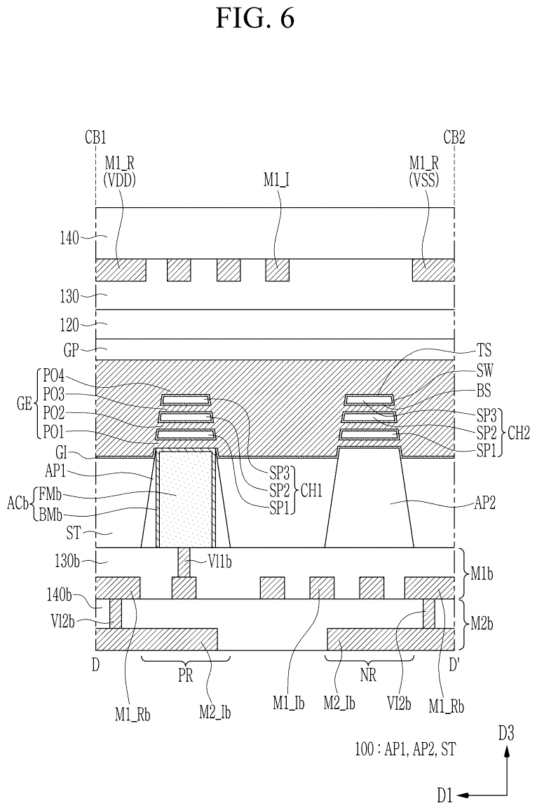

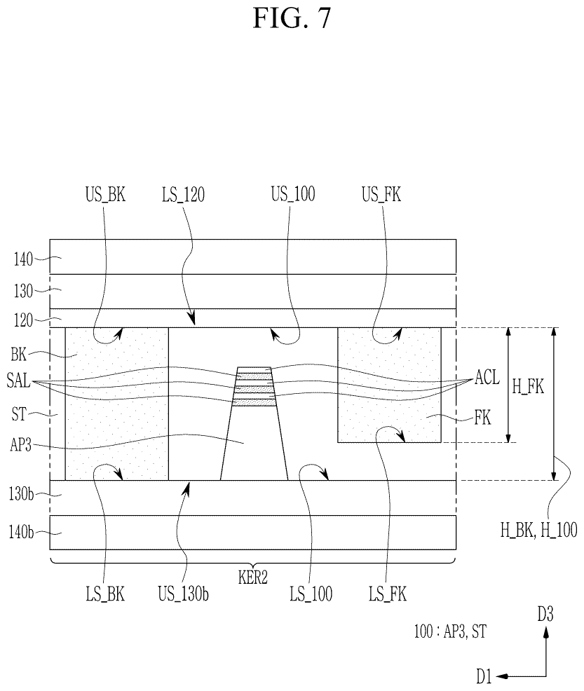

FIG. 1 is a top plan view illustrating a semiconductor device according to an embodiment. FIG. 2 is a top plan view illustrating a logic cell region CER of FIG. 1. FIG. 3 is a cross-sectional view taken along line A-A′ of FIG. 2. FIG. 4 is a cross-sectional view taken along line B-B′ of FIG. 2. FIG. 5 is a cross-sectional view taken along line C-C′ of FIG. 2. FIG. 6 is a cross-sectional view taken along line D-D′ of FIG. 2. FIG. 7 is a cross-sectional view showing a second overlay key region KER2 of FIG. 1. FIG. 7 may be the cross-sectional view revealed in the second overlay key region KER2 when taken along line D-D′ of FIG. 2 as shown in FIG. 6.

For clear understanding and brief illustration, in FIG. 2, a separation structure DB, a first cell boundary CB1, a second cell boundary CB2, a first upper metal layer M1, a second upper metal layer M2, a gate pattern GE, an upper active contact AC, an upper gate contact GC, a lower active contact ACb, and a lower gate contact GCb are mainly illustrated.

Referring to FIG. 1, the semiconductor device may include a main chip MC and a cut scribe lane CSL surrounding the main chip MC in the plan view. The main chip MC may include first to fifth functional units FE1 to FE5 on a substrate 100. The substrate 100 may be a diced semiconductor wafer. The substrate 100 may support the first to fifth functional units FE1 to FE5.

The main chip MC may include first to fourth boundaries CB1 to CB4. The first to fourth boundaries CB1 to CB4 may be defined between the cut scribe lane CSL and the main chip MC. The cut scribe lane CSL may surround the first to fourth boundaries CB1 to CB4 of the main chip MC in the plan view. For example, the cut scribe lane CSL may include a first overlay key region KER1 adjacent to the first boundary CB1 of the main chip MC. In other words, the first overlay key region KER1 may remain on the cut scribe lane CSL even after a wafer dicing process.

Each of the first to fifth functional units FE1 to FE5 may be a functional block constituting an integrated circuit. Each of the first to fifth functional units FE1 to FE5 may include a memory block, an analog logic block, an input/output (I/O) logic block, a central processing unit (CPU) block, a radio frequency block, or a combination of these.

For example, the first functional unit FE1 may include the logic cell region CER and the second overlay key region KER2. In other words, an overlay key region may be disposed not only in a scribe lane but also within a functional block. A third overlay key region KER3 may be disposed in a region between the first functional unit FEL and the second functional unit FE2.

In the semiconductor device, that is, a semiconductor chip, at least one of the first to third overlay key regions KER1, KER2, and KER3 may be omitted.

Referring to FIGS. 2 to 7, the semiconductor device includes the substrate 100 including the logic cell region CER including first and second active patterns AP1 and AP2, and the second overlay key region KER2 including a back-side key pattern BK and a front-side key pattern FK, first and second source/drain patterns SD1 and SD2 located on the first and second active patterns AP1 and AP2 of the logic cell region CER, first and second channel patterns CH1 and CH2 located between the first and second source/drain patterns SD1 and SD2, and the gate pattern GE crossing between the first and second source/drain patterns SD1 and SD2 and surrounding at least a part of the first and second channel patterns CH1 and CH2.

The substrate 100 includes the logic cell region CER and the second overlay key region KER2.

Logic transistors constituting a logic cell LC may be disposed in the logic cell region CER of the substrate 100. The logic cell LC may include a PMOSFET region PR and an NMOSFET region NR.

The PMOSFET region PR and the NMOSFET region NR may be defined by the first and second active patterns AP1 and AP2 constituting the substrate 100. In other words, the first and second active patterns AP1 and AP2 may be disposed in the PMOSFET region PR and the NMOSFET region NR, respectively.

The first and second active patterns AP1 and AP2 are parts of the substrate 100 and may be parts that protrude in the third direction D3. The first and second active patterns AP1 and AP2 may be spaced apart in the first direction D1. The first and second active patterns AP1 and AP2 may extend in the second direction D2.

The first and second active patterns AP1 and AP2 may each include silicon (Si) or germanium (Ge), which are element semiconductor materials. In addition, the first and second active patterns AP1 and AP2 may each include a compound semiconductor, for example, a group IV-IV compound semiconductor or a group III-V compound semiconductor. The group IV-IV compound semiconductor may be, for example, a binary compound or a ternary compound including carbon (C), silicon (Si), germanium (Ge), tin (Sn), or a combination thereof. The group III-V compound semiconductor may be, for example, a binary compound, a ternary compound, or a quaternary compound formed by combining a group III element such as aluminum (Al), gallium (Ga), indium (In), or a combination thereof, and a group V element such as phosphorus (P), arsenic (As), antimonium (Sb) or a combination thereof.

A device isolation layer ST may be located between the first and second active patterns AP1 and AP2. In other words, the device isolation layer ST may be located next to the first and second active patterns AP1 and AP2 in the first direction D1. The device isolation layer ST may be in and at least partially fill trenches between the first and second active patterns AP1 and AP2.

Upper portions of the first and second active patterns AP1 and AP2 may protrude in the third direction D3 rather than the device isolation layer ST. In other words, the device isolation layer ST may not cover or overlap the upper portions of the first and second active patterns AP1 and AP2 in the third direction D3. The device isolation layer ST may cover sidewalls of the first and second active patterns AP1 and AP2 in the first direction D1.

For example, the device isolation layer ST may include an insulating material, for example, silicon nitride (SiN), silicon nitride (SiON), or a combination thereof. Although the device isolation layer ST is illustrated as a single layer, the present disclosure is not limited thereto.

The first active pattern AP1 may include the first channel pattern CH1 on an upper portion thereof. The second active pattern AP2 may include a second channel pattern CH2 on an upper portion thereof. Each of the first and second channel patterns CH1 and CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in the third direction D3.

For example, in FIGS. 4 and 6, the three first to third semiconductor patterns SP1, SP2, and SP3 are spaced apart and stacked in the third direction D3, but embodiments of the present disclosure are not limited thereto. For example, two semiconductor patterns may be spaced apart and stacked in the third direction D3, or four or more semiconductor patterns may be spaced apart and stacked in the third direction D3.

In addition, for example, in FIGS. 4 and 6, side surfaces of the first to third semiconductor patterns SP1, SP2, and SP3 are flat surfaces, but embodiments of the present disclosure are not limited thereto. For example, the side surfaces of the first to third semiconductor patterns SP1, SP2, and SP3 may be a combination of curved and flat surfaces, or may be entirely curved.

Each of the first and second channel patterns CH1 and CH2 may include an element semiconductor material, such as silicon (Si), silicon germanium (SiGe), group IV-IV compound semiconductor, or group III-V compound semiconductor. Each of the first and second channel patterns CH1 and CH2 may include the same material as each of the first and second active patterns AP1 and AP2, and may include a different material from each of the first and second active patterns AP1 and AP2.

A plurality of first recesses RS1 may be formed in the upper portion of the first active pattern AP1. The first source/drain patterns SD1 may be disposed in the first recesses RS1. The first source/drain patterns SD1 may be impurity regions of a first conductivity type (e.g., p-type). The first channel pattern CH1 may be disposed between a pair of first source/drain patterns SD1. In other words, the stacked first to third semiconductor patterns SP1, SP2, and SP3 may electrically connect the pair of first source/drain patterns SD1 to each other.

A plurality of second recesses RS2 may be formed in the upper portion of the second active pattern AP2. The second source/drain patterns SD2 may be disposed in the second recesses RS2. The second source/drain patterns SD2 may be impurity regions of a second conductivity type (e.g., n-type). The second channel pattern CH2 may be disposed between a pair of second source/drain patterns SD2. In other words, the stacked first to third semiconductor patterns SP1, SP2, and SP3 may electrically connect the pair of second source/drain patterns SD2 to each other.

For example, the first and second source/drain patterns SD1 and SD2 may be epitaxial patterns formed through a selective epitaxial growth (SEG) process. An upper surface of each of the first and second source/drain patterns SD1 and SD2 may be located at substantially the same level in the third direction D3 as an upper surface of the third semiconductor pattern SP3. In some embodiments, the upper surface of each of the first and second source/drain patterns SD1 and SD2 may be higher than the upper surface of the third semiconductor pattern SP3 in the third direction D3.

For example, the first source/drain pattern SD1 may include a first semiconductor layer and a second semiconductor layer on the first semiconductor layer.

The first semiconductor layer may be on and at least partially cover an inner wall of the first recess RS1. The thickness of the first semiconductor layer may be thinner from a lower portion thereof to an upper portion thereof. For example, the thickness of the first semiconductor layer on the bottom of the first recess RS1 in the third direction D3 may be greater than the thickness of the first semiconductor layer on the top of the first recess RS1 in the second direction D2. The first semiconductor layer may have a U-shape along a profile of the first recess RS1.

The second semiconductor layer may be in and at least partially fill the remaining region of the first recess RS1 excluding the first semiconductor layer. The volume of the second semiconductor layer may be larger than the volume of the first semiconductor layer. In other words, a ratio of the volume of the second semiconductor layer to the total volume of the first source/drain pattern SD1 may be greater than a ratio of the volume of the first semiconductor layer to the total volume of the first source/drain pattern SD1.

Each of the first semiconductor layer and the second semiconductor layer may include silicon-germanium (SiGe). For example, the first semiconductor layer may contain germanium (Ge) of a relatively low concentration. In some embodiments, the first semiconductor layer may include only silicon (Si) excluding germanium (Ge). The concentration of germanium (Ge) in the first semiconductor layer may be 0 at % to 10 at %.

The second semiconductor layer may contain germanium (Ge) at a relatively high concentration. For example, the concentration of germanium (Ge) in the second semiconductor layer may be 30 at % to 70 at %. The concentration of germanium (Ge) in the second semiconductor layer may increase in the third direction D3. For example, the second semiconductor layer adjacent to the first semiconductor layer may include germanium (Ge) at a concentration of about 40 at %, but an upper portion of the second semiconductor layer may include germanium (Ge) at a concentration of about 60 at %.

The first and second semiconductor layers may each include impurities (e.g., boron) allowing the first source/drain pattern SD1 to have a p-type. The concentration (e.g., atomic percent) of impurities in the second semiconductor layer may be greater than the concentration of impurities in the first semiconductor layer.

The gate pattern GE extends in the first direction D1 across the first and second active patterns AP1 and AP2. The gate patterns GE may be spaced apart in the second direction D2 by a first pitch P1. Each of the gate patterns GE may overlap the first and second channel patterns CH1 and CH2 in the third direction D3.

For example, the gate pattern GE may include a first portion PO1 disposed between the first and second active patterns AP1 and AP2 and the first semiconductor pattern SP1, a second portion PO2 disposed between the first semiconductor pattern SP1 and the second semiconductor pattern SP2, a third portion PO3 disposed between the second semiconductor pattern SP2 and the third semiconductor pattern SP3, and a fourth portion PO4 above the third semiconductor pattern SP3 in the third direction D3.

The gate pattern GE may be disposed on a top surface TS, a bottom surface BS, and both sidewalls SW of each of the first to third semiconductor patterns SP1, SP2, and SP3. In other words, the gate pattern GE may surround at least a part of the first and second channel patterns CH1 and CH2.

A pair of gate spacers GS may be disposed on both sidewalls of the fourth portion PO4 of the gate pattern GE. The gate spacers GS may extend in the first direction D1 along the gate pattern GE. Upper surfaces of the gate spacers GS may be higher than an upper surface of the gate pattern GE in the third direction D3. The upper surfaces of the gate spacers GS may be located at substantially the same level as an upper surface of a first interlayer insulating layer 110, which will be described below. The gate spacer GS may include SiCN, SiCON, SiN, or a combination thereof. In addition, the gate spacer GS may include a multi-layer including SiCN, SiCON, SiN, or a combination thereof.

A gate capping pattern GP may be disposed on the gate pattern GE. The gate capping pattern GP may extend in the first direction D1 along the gate pattern GE. The gate capping pattern GP may include a material having etch selectivity with respect to first and second interlayer insulating layers 110 and 120, which will be described below. For example, the gate capping pattern GP may include SiON, SiCN, SiCON, SiN, or a combination thereof.

Gate insulating layers GI may be disposed between the gate pattern GE and the first channel pattern CH1 and between the gate electrode GE and the second channel pattern CH2. The gate insulating layer GI may at least partially cover the top surface TS, the bottom surface BS, and both sidewalls SW of each of the first to third semiconductor patterns SP1, SP2, and SP3. The gate insulating layer GI may at least partially cover an upper surface of the device isolation layer ST below the gate pattern GE.

The gate insulating layer GI may include a silicon oxide layer, a silicon oxynitride layer, a high-k dielectric layer, or a combination thereof. The high-k dielectric layer may include a high dielectric constant material having a higher dielectric constant than that of the silicon oxide layer. For example, the high dielectric constant material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

In some embodiments, the gate pattern GE may include a first metal pattern and a second metal pattern on the first metal pattern. The first metal pattern may be disposed on the gate insulating layer GI and adjacent to the first to third semiconductor patterns SP1, SP2, and SP3. The first metal pattern may include a work function metal that adjusts a threshold voltage of a transistor. The desired threshold voltage of the transistor may be achieved by adjusting the thickness and composition of the first metal pattern. For example, the first to third portions PO1, PO2, and PO3 of the gate pattern GE may include the first metal pattern that is a work function metal.

The first metal pattern may include a metal nitride layer. For example, the first metal pattern may include titanium (Ti), tantalum (Ta), aluminum (Al), tungsten (W), molybdenum (Mo), or a combination thereof. In addition, the first metal pattern may further include carbon (C). The first metal pattern may include a plurality of stacked work function metal layers.

The second metal pattern may include a metal having lower resistance than the first metal pattern. For example, the second metal pattern may include a metal including tungsten (W), aluminum (Al), titanium (Ti), tantalum (Ta), or a combination thereof. For example, the fourth portion PO4 of the gate pattern GE may include the first metal pattern and the second metal pattern on the first metal pattern.

Although not shown, inner spacers may be located on the NMOSFET region NR. The inner spacers may be disposed between the first to third portions PO1, PO2, and PO3 of the gate electrode GE and the second source/drain pattern SD2, respectively. The inner spacers may directly contact the second source/drain pattern SD2. Each of the first to third portions PO1, PO2, and PO3 of the gate electrode GE may be spaced apart from the second source/drain pattern SD2 by the inner spacer.

The first interlayer insulating layer 110 may be disposed on the substrate 100. The first interlayer insulating layer 110 may at least partially cover the gate spacer GS and the first and second source/drain patterns SD1 and SD2. The upper surface of the first interlayer insulating layer 110 may be located at substantially the same level as an upper surface of the gate capping pattern GP and the upper surface of the gate spacer GS in the third direction D3.

The second interlayer insulating layer 120 at least partially covering the gate capping pattern GP may be disposed on the first interlayer insulating layer 110.

For example, the first and second interlayer insulating layers 110 and 120 may each include a silicon oxide layer.

Referring again to FIGS. 2 to 4, a pair of separation structures DB facing each other in the second direction D2 may be disposed on both sides of the logic cell LC. The separation structure DB may extend parallel to the gate pattern GE in the first direction D1. A pitch between the separation structure DB and the gate pattern GE adjacent thereto may be the same as the first pitch P1.

The separation structure DB may penetrate or extend into the first and second interlayer insulating layers 110 and 120 and extend into the first and second active patterns AP1 and AP2. The separation structure DB may penetrate or extend into the upper portion of each of the first and second active patterns AP1 and AP2. The separation structure DB may separate the PMOSFET region PR and the NMOSFET region NR of the logic cell LC from active regions of adjacent logic cells.

The upper portion of each of the first and second active patterns AP1 and AP2 may further include sacrificial layers SAL adjacent to the separation structure DB. The sacrificial layers SAL may be stacked to be spaced apart from each other. The sacrificial layers SAL may be respectively located at the same level as the first to third portions PO1, PO2, and PO3 of the gate pattern GE in the third direction D3. The separation structure DB may penetrate or extend into the sacrificial layers SAL.

The sacrificial layers SAL may include silicon-germanium (SiGe). The concentration of germanium (Ge) in each of the sacrificial layers SAL may be 10 at % to 30 at %. The concentration of germanium (Ge) in the sacrificial layer SAL may be higher than the concentration of germanium (Ge) in the first semiconductor layer described above.

The upper active contacts AC may penetrate or extend into the first and second interlayer insulating layers 110 and 120 and be electrically connected to the first and second source/drain patterns SD1 and SD2, respectively. For example, a pair of upper active contacts AC may be disposed between the gate patterns GE. From a plan view, the upper active contact AC may have a bar shape extending in the first direction D1.

Silicide patterns SC may be disposed between the upper active contact AC and the first source/drain pattern SD1 and between the upper active contact AC and the second source/drain pattern SD2, respectively. The upper active contact AC may be electrically connected to each of the first and second source/drain patterns SD1 and SD2 through the silicide pattern SC. The silicide pattern SC may include metal-silicide, for example, titanium-silicide, tantalum-silicide, tungsten-silicide, nickel-silicide, cobalt-silicide, or a combination thereof.

The upper gate contact GC may penetrate or extend into the second interlayer insulating layer 120 and the gate capping pattern GP and be electrically connected to the gate pattern GE. For example, referring to FIG. 4, an upper portion of each of the upper active contacts AC adjacent to the upper gate contact GC may be at least partially filled with an upper insulating pattern UIP. Accordingly, a process defect in which a short circuit occurs due to the upper gate contact GC contacting the adjacent upper active contact AC may be reduced or prevented.

Each of the upper active contact AC and the upper gate contact GC may include a conductive pattern FM and a barrier pattern BM at least partially surrounding the conductive pattern FM. For example, the conductive pattern FM may include aluminum, copper, tungsten, molybdenum, or a combination thereof. The barrier pattern BM may at least partially cover sidewalls and a bottom surface of the conductive pattern FM. The barrier pattern BM may include a metal layer or a metal nitride layer. The metal layer may include titanium, tantalum, tungsten, nickel, cobalt, platinum, or a combination thereof. The metal nitride layer may include titanium nitride layer (TiN), tantalum nitride layer (TaN), tungsten nitride layer (WN), nickel nitride layer (NiN), cobalt nitride layer (CON), platinum nitride layer (PtN), or a combination thereof.

A first upper interlayer insulating layer 130 may be located above the upper active contact AC and the upper gate contact GC in the third direction D3 and at least partially cover the upper active contact AC and the upper gate contact GC.

A first upper metal layer M1 may be disposed within the first upper interlayer insulating layer 130. The first upper metal layer M1 may include first upper power wirings M1_R, first upper wirings M1_I, and first upper vias VI1.

The first upper vias V11 may be disposed below the first upper power wirings M1_R and the first upper wirings M1_I in the third direction D3.

Each of the first upper power wirings M1_R may extend in the second direction D2 across the logic cell LC. Each of the first upper power wirings M1_R may be a power wiring. For example, a drain voltage VDD or a source voltage VSS may be applied to the first upper power wiring M1_R.

Referring to FIG. 2, the first cell boundary CB1 extending in the second direction D2 may be defined in the logic cell LC. In the logic cell LC, the second cell boundary CB2 extending in the second direction D2 may be defined on the opposite side of the first cell boundary CB1. The first upper power wiring M1_R to which the drain voltage VDD, that is, a power voltage, is applied may be disposed on the first cell boundary CB1. The first upper power wiring M1_R to which the drain voltage VDD is applied may extend in the second direction D2 along the first cell boundary CB1. The first upper power wiring M1_R to which the source voltage VSS, that is, a ground voltage, is applied may be disposed on the second cell boundary CB2. The first upper power wiring M1_R to which the source voltage VSS is applied may extend in the second direction D2 along the second cell boundary CB2.

The first upper wirings M1_I may be disposed in the first direction D1 between the first upper power wiring M1_R to which the drain voltage VDD is applied and the first upper power wiring M1_R to which the source voltage VSS is applied. Each of the first upper wirings M1_I may have a line shape or a bar shape extending in the second direction D2. The first upper wirings M1_I may be arranged along the first direction D1 at a second pitch P2. The second pitch P2 may be smaller than the first pitch P1.

The first upper vias V11 may be disposed below the first upper power wirings M1_R and the first upper wirings M1_I. The first upper vias V11 may be disposed between the upper active contact AC and the first upper power wirings M1_R and first upper wirings M1_I, respectively. In addition, the first upper vias V11 may be respectively disposed between the upper gate contact GC and the first upper wirings M1_I.

A second upper interlayer insulating layer 140 may be located on the first upper interlayer insulating layer 130 and at least partially cover the first upper interlayer insulating layer 130.

A second upper metal layer M2 may be disposed within the second upper interlayer insulating layer 140. The second upper metal layer M2 may include second upper wirings M2_I. Each of the second upper wirings M2_I may have a line shape or a bar shape extending in the first direction D1. In other words, the second upper wirings M2_I may extend parallel to each other in the first direction D1. From a plan view, the second upper wirings M2_I may be parallel to the gate pattern GE. The second upper wirings M2_I may be disposed along the second direction D2 at a third pitch P3. The third pitch P3 may be smaller than the first pitch P1. The third pitch P3 may be greater than the second pitch P2.

The second upper metal layer M2 may further include second upper vias VI2. The second upper vias VI2 may be disposed below the second upper wirings M2_I in the third direction D3. The second upper vias VI2 may be disposed between the first upper power wirings M1_R and the first upper wirings M1_I and the second upper wirings M2_I, respectively.

The first upper power wirings M1_R and the first upper wirings M1_I of the first upper metal layer M1 and the second upper wirings M2_I of the second upper metal layer M2 may include the same conductive material as or different conductive materials from each other. For example, the first upper power wirings M1_R, the first upper wirings M1_I, and the second upper wirings M2_I may include aluminum, copper, tungsten, molybdenum, cobalt, or a combination thereof.

Although not shown, in some embodiments, upper metal layers (e.g., M3, M4, M5, etc.) stacked on the second upper interlayer insulating layer 140 may be additionally disposed. Each of the stacked upper metal layers may include routing wirings.

The lower active contact ACb may be located below the first and second source/drain patterns SD1 and SD2 in the third direction D3, and electrically connected to the first and second source/drain patterns SD1 and SD2, respectively. From a plan view, the lower active contact ACb may have a bar shape extending in the first direction D1.

For example, the lower active contact ACb may penetrate or extend into the first and second active patterns AP1 and AP2 and be electrically connected to the first and second source/drain patterns SD1 and SD2, respectively.

The silicide patterns SC may be disposed between the lower active contact ACb and the first source/drain pattern SD1, and between the lower active contact ACb and the second source/drain pattern SD2, respectively. The lower active contact ACb may be electrically connected to the first and second source/drain patterns SD1 and SD2 through the silicide pattern SC. The silicide pattern SC may include metal-silicide, for example, titanium-silicide, tantalum-silicide, tungsten-silicide, nickel-silicide, cobalt-silicide, or a combination thereof.

The lower gate contact GCb may be located below the gate pattern GE in the third direction D3 and electrically connected to the gate pattern GE. For example, the lower gate contact GCb may penetrate or extend into the first active pattern AP1 and be electrically connected to the first source/drain pattern SD1. However, embodiments of the present disclosure are not limited thereto, and the lower gate contact GCb may penetrate or extend into the second active pattern AP2 and be electrically connected to the second source/drain pattern SD1.

Each of the lower active contact ACb and the lower gate contact GCb may include the conductive pattern FM and the barrier pattern BM at least partially surrounding the conductive pattern FM. For example, the conductive pattern FM may include a metal including aluminum, copper, tungsten, molybdenum, or a combination thereof. The barrier pattern BM may at least partially cover the sidewalls and the bottom surface of the conductive pattern FM. The barrier pattern BM may include a metal layer or a metal nitride layer. The metal layer may include titanium, tantalum, tungsten, nickel, cobalt, platinum, or a combination thereof. The metal nitride layer may include titanium nitride layer (TiN), tantalum nitride layer (TaN), tungsten nitride layer (WN), nickel nitride layer (NiN), cobalt nitride layer (CON), platinum nitride layer (PtN), or a combination thereof.

A first lower interlayer insulating layer 130b may be located below the lower active contact ACb and the lower gate contact GCb in the third direction D3, and at least partially cover the lower active contact ACb and the lower gate contact GCb.

A first lower metal layer Mlb may be disposed within the first lower interlayer insulating layer 130b. The first lower metal layer Mlb may include first lower power wirings M1_Rb, first lower wirings M1_Ib, and first lower vias VI1b. The first lower vias VIlb may be disposed on the first lower power wirings M1_R and the first lower wirings M1_I.

Each of the first lower power wirings M1_Rb may extend in the second direction D2 across the logic cell LC. The first lower power wirings M1_Rb may be power wirings. For example, the drain voltage VDD or the source voltage VSS may be applied to the first lower power wiring M1_Rb.

The first lower power wiring M1_Rb to which the drain voltage VDD is applied may extend in the second direction D2. In addition, the first lower power wiring M1_Rb to which the source voltage VSS is applied may extend in the second direction D2.

The first lower wirings M1_Ib may be disposed in the first direction D1 between the first lower power wiring M1_Rb to which the drain voltage VDD is applied and the first lower power wiring M1_Rb to which the source voltage VSS is applied. Each of the first lower wirings M1_Ib may have a line shape or a bar shape extending in the second direction D2. The first lower wirings M1_Ib may be disposed in the first direction D1 at the second pitch P2. The second pitch P2 may be smaller than the first pitch P1.

The first lower vias VI1b may be disposed above the first lower power wirings M1_Rb and the first lower wirings M1_Ib in the third direction D3. The first lower vias VI1 may be disposed between the lower active contact ACb and the first lower power wirings M1_Rb and first lower wirings M1_Ib, respectively. In addition, the first lower vias V11 may be disposed between the lower gate contact GCb and the first lower wirings M1_Ib, respectively.

A second lower interlayer insulating layer 140b may be located below the first lower interlayer insulating layer 130b in the third direction D3 and at least partially cover the first lower interlayer insulating layer 130b.

A second lower metal layer M2b may be disposed within the second lower interlayer insulating layer 140b. The second lower metal layer M2b may include second lower wirings M2_Ib. Each of the second lower wirings M2_Ib may have a line shape or a bar shape extending in the first direction D1. In other words, the second lower wirings M2_Ib may extend parallel to each other in the first direction D1. From a plan view, the second lower wirings M2_Ib may be parallel to the gate pattern GE. The second lower wirings M2_Ib may be disposed in the second direction D2 at the third pitch P3. The third pitch P3 may be smaller than the first pitch P1. The third pitch P3 may be greater than the second pitch P2.

The second lower metal layer M2b may further include second lower vias VI2b. The second lower vias VI2 may be disposed above the second lower wirings M2_Ib in the third direction D3. The second lower vias VI2b may be disposed between the first lower power wirings M1_Rb, the first lower wirings M1_Ib, and the second lower wirings M2_I, respectively.

The first lower power wirings M1_Rb and the first lower wirings M1_Ib of the first lower metal layer Mlb and the second lower wirings M2_Ib of the second lower metal layer M2b may include the same conductive material as or different conductive materials from each other. For example, the first lower power wirings M1_Rb, the first lower wirings M1_Ib, and the second lower wirings M2_Ib may include aluminum, copper, tungsten, molybdenum, cobalt, or a combination thereof.

Referring to FIG. 7, the second overlay key region KER2 of the substrate 100 includes the back-side key pattern BK and the front-side key pattern FK.

The back-side key pattern BK and the front-side key pattern FK may be located within the substrate 100. For example, the back-side key pattern BK and the front-side key pattern FK may be located within the device isolation layer ST.

The back-side key pattern BK and the front-side key pattern FK may be parts extending in the third direction D3 within the device isolation layer ST. On the plane, a plurality of back-side key patterns BK may be spaced apart at a constant pitch and disposed two-dimensionally. For example, the back-side key pattern BK may be disposed in a checkerboard shape in the first direction D1 and the second direction D2. Similarly, on the plane, a plurality of front-side key patterns FK may be spaced apart at a constant pitch and disposed two-dimensionally. For example, the front-side key pattern FK may be disposed in the checkerboard shape in the first direction D1 and the second direction D2. For example, the back-side key pattern BK and the front-side key pattern FK may each include silicon oxide.

The substrate 100 may have a first surface and a second surface facing each other in the third direction D3. The first surface of the substrate 100 is located closer to the first lower interlayer insulating layer 130b than the second surface. In other words, the first surface of the substrate 100 may be a lower surface LS_100, and the second surface of the substrate 100 may be an upper surface US_100.

In addition, the back-side key pattern BK may have a first surface and a second surface facing each other in the third direction D3. The first surface of the back-side key pattern BK is located closer to the first lower interlayer insulating layer 130b than the second surface. In other words, the first surface of the back-side key pattern BK may be a lower surface LS_BK, and the second surface of the back-side key pattern BK may be an upper surface US_BK.

In addition, the front-side key pattern FK may have a first surface and a second surface facing each other in the third direction D3. The first surface of the front-side key pattern FK is located closer to the first lower interlayer insulating layer 130b than the second surface. In other words, the first surface of the front-side key pattern FK may be a lower surface LS_FK, and the second surface of the back-side key pattern BK may be an upper surface US_FK.

For example, with respect to the first lower interlayer insulating layer 130b, the lower surface LS_BK of the back-side key pattern BK may be located at substantially the same level as the lower surface LS_100 of the substrate 100 in the third direction D3, i.e., the lower surface LS_BK of the back-side key pattern BK and the lower surface LS_100 of the substrate 100 may be generally coplanar. That is, the lower surface LS_BK of the back-side key pattern BK may penetrate or extend into the lower surface LS_100 of the substrate 100 and contact an upper surface US_130b of the first lower interlayer insulating layer 130b.

With respect to the first lower interlayer insulating layer 130b, the upper surface US_BK of the back-side key pattern BK may be located at substantially the same level as the upper surface US_100 of the substrate 100 in the third direction D3. That is, the upper surface US_BK of the back-side key pattern BK may penetrate or extend into the upper surface US_100 of the substrate 100 and contact a lower surface LS_120 of the second interlayer insulating layer 120.

In other words, the back-side key pattern BK may extend from the lower surface LS_100 of the substrate 100 to the upper surface US_100 in the third direction D3, and the back-side key pattern BK may completely penetrate or extend from the lower surface LS_100 of the substrate 100 to the upper surface US_100 in the third direction D3.

Accordingly, when the back-side key pattern BK exposed on the lower surface LS_100 of the substrate 100 is used, the lower gate contact GCb may be aligned with the gate pattern GE located on the front surface when formed, and the lower active contact ACb may be aligned with the first and second source/drain patterns SD1 and SD2 located on the front surface, when the lower active contact ACb is formed after the lower gate contact GCb is first formed, the lower gate contact GCb and the lower active contact ACb may be aligned, or when the lower gate contact GCb is formed after the lower active contact ACb is first formed, the lower active contact ACb and the lower gate contact GCb may be aligned. Accordingly, when a back-side power distribution network (BSPDN) structure is applied, alignment errors between the lower active contact ACb and the lower gate contact GCb located on the back surface and the first and second source/drain patterns SD1 and SD2 and the gate pattern GE located on the front surface may be reduced.

The front-side key pattern FK may be spaced apart from the lower surface LS_100 of the substrate 100. In other words, with respect to the first lower interlayer insulating layer 130b, the lower surface LS_FK of the front-side key pattern FK may be located at a higher level than the lower surface LS_100 of the substrate 100 in the third direction D3. That is, the lower surface LS_FK of the front-side key pattern FK may be located farther from the first lower interlayer insulating layer 130b than the lower surface LS_100 of the substrate 100. Accordingly, the lower surface LS_KF of the front-side key pattern FK does not penetrate or extend into the lower surface LS_100 of the substrate 100 and does not contact the upper surface US_130b of the first lower interlayer insulating layer 130b.

With respect to the first lower interlayer insulating layer 130b, the upper surface US_FK of the front-side key pattern FK may be located at substantially the same level as the upper surface US_100 of the substrate 100 in the third direction D3, i.e., the upper surface US_FK of the front-side key pattern FK and the upper surface US_100 of the substrate 100 may be generally coplanar. That is, the upper surface US_FK of the front-side key pattern FK may penetrate or extend into the upper surface US_100 of the substrate 100 and contact the lower surface LS_120 of the second interlayer insulating layer 120.

Accordingly, when the front-side key pattern FK exposed on the upper surface US_100 of the substrate 100 is used, the upper gate contact GC may be aligned with the gate pattern GE when formed, and the upper active contact AC may be aligned with the first and second source/drain patterns SD1 and SD2 when formed, when the upper active contact AC is formed after the upper gate contact GC is first formed, the upper gate contact GC and the upper active contact AC may be aligned, or when the upper gate contact GC is formed after the upper active contact AC is first formed, the upper active contact AC and the upper gate contact GC may be aligned.

As described above, with respect to the first lower interlayer insulating layer 130b, the lower surface LS_BK of the back-side key pattern BK is located substantially at the same level as the lower surface LS_100 of the substrate 100 in the third direction D3, and the lower surface LS_FK of the front-side key pattern FK is located at a higher level than the lower surface LS_100 of the substrate 100 in the third direction D3, and thus, the lower surface LS_BK of the back-side key pattern BK may be located closer to the lower surface LS_100 of the substrate 100 than the lower surface LS_FK of the front-side key pattern FK.

In addition, with respect to the first lower interlayer insulating layer 130b, a length H_BK of the back-side key pattern BK in the third direction D3 may be substantially the same as a length H_100 of the substrate 100 in the third direction D3. The length H_BK of the back-side key pattern BK in the third direction D3 may be greater than a length H_FK of the front-side key pattern FK in the third direction D3. With respect to the first lower interlayer insulating layer 130b, the length H_FK of the front-side key pattern FK in the third direction D3 may be less than the length H_100 of the substrate 100 in the third direction D3.

Here, the length H_100 of the substrate 100 in the third direction D3 may be the shortest length in the third direction D3 from the lower surface LS_100 of the substrate 100 to the upper surface US_100, the length H_BK of the back-side key pattern BK in the third direction D3 may be the shortest length in the third direction D3 from the lower surface LS_BK of the back-side key pattern BK to the upper surface US_BK, and the length H_FK of the front-side key pattern FK in the third direction D3 may be the shortest length in the third direction D3 from the lower surface LS_FK of the front-side key pattern FK to the upper surface US_FK.

A third active pattern AP3 may be disposed on the second overlay key region KER2 of the substrate 100.

The third active patterns AP3 are parts of the substrate 100 and may be portions that protrude in the third direction D3. The third active patterns AP3 may be spaced apart in the first direction D1. The third active pattern AP3 may extend in the second direction D2.

The third active pattern AP3 may include silicon (Si) or germanium (Ge), which is an element semiconductor material. In addition, the third active pattern AP3 may include a compound semiconductor, for example, a group IV-IV compound semiconductor or a group III-V compound semiconductor. The group IV-IV compound semiconductor may be, for example, a binary compound or a ternary compound including carbon (C), silicon (Si), germanium (Ge), tin (Sn), or a combination thereof. The group III-V compound semiconductor may be, for example, a binary compound, a ternary compound, or a quaternary compound formed by combining a group III element such as aluminum (Al), gallium (Ga), indium (In), or a combination thereof, a group V element such as phosphorus (P), arsenic (As), antimony (Sb) or a combination thereof.

For example, in the second overlay key region KER2, the device isolation layer ST may at least partially cover the third active pattern AP3. In other words, in the second overlay key region KER2, the device isolation layer ST of the substrate 100 may extend from the lower surface LS_100 of the substrate 100 to the upper surface US_100 in the third direction D3, and the device isolation layer ST may contact the lower surface LS_120 of the second interlayer insulating layer 120. As described above, the back-side key pattern BK and the front-side key pattern FK may be located within the device isolation layer ST.

The device isolation layer ST may be located between the third active patterns AP3. In other words, the device isolation layer ST may be located next to the third active pattern AP3 in the first direction D1. The device isolation layer ST may at least partially fill trenches between the third active patterns AP3.

In FIG. 7, the back-side key pattern BK and the front-side key pattern FK are located on both sides of the third active pattern AP3 in the first direction D1, but embodiments of the present disclosure are not limited thereto, and the arrangement order and shapes of the third active pattern AP3, the back-side key pattern BK, and the front-side key pattern FK are not limited, such as the third active pattern AP3 may be located only on one side of the back-side key pattern BK, or may be located only on one side of the front-side key pattern FK, etc. In addition, in FIG. 7, the third active pattern AP3, the back-side key pattern BK, and the front-side key pattern FK are each disposed one by one, but embodiments of the present disclosure are not limited thereto, and a plurality of third active patterns AP3, a plurality of back-side key patterns BK, and a plurality of front-side key patterns FK may be disposed in the first direction D1.

For example, in the second overlay key region KER2, the sacrificial layers SAL and active layers ACL may be disposed on the third active pattern AP3.

The sacrificial layers SAL and the active layers ACL may be alternately stacked in the third direction D3. The sacrificial layers SAL may be stacked to be spaced apart from each other in the third direction D3, and the active layers ACL may be stacked to be spaced apart from each other in the third direction D3. The sacrificial layers SAL may be located at the same level as the first to third portions PO1, PO2, and PO3 of the gate pattern GE of the logic cell region CER, respectively, in the third direction D3.

The sacrificial layers SAL may include silicon (Si), germanium (Ge), or silicon-germanium (SiGe), and the active layers ACL may include silicon (Si), germanium (Ge), or silicon-germanium (SiGe). For example, the sacrificial layers SAL may include silicon-germanium (SiGe), and the active layers ACL may include silicon (Si). The concentration of germanium (Ge) in each of the sacrificial layers SAL may be 10 at % to 30 at %.

For example, the lower surface LS_FK of the front-side key pattern FK may be located at a lower level than the sacrificial layers SAL in the third direction D3. Here, the level of the sacrificial layers SAL in the third direction D3 may be a level in the third direction D3 at a part where the sacrificial layer SAL located at the lowest end contacts the third active pattern AP3 with respect to the first lower interlayer insulating layer 130b.

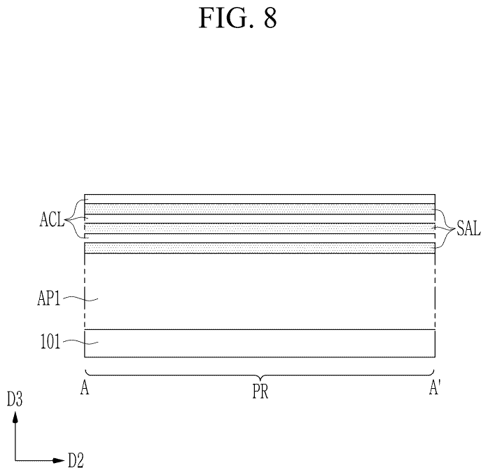

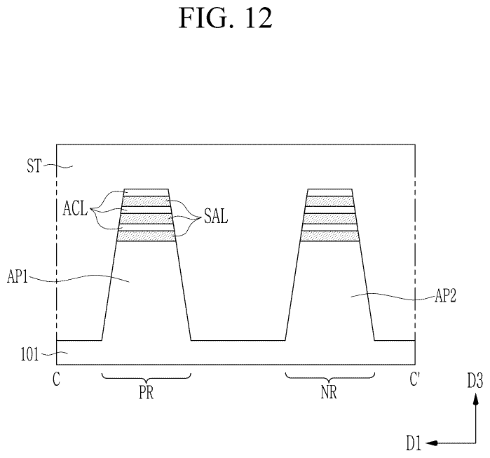

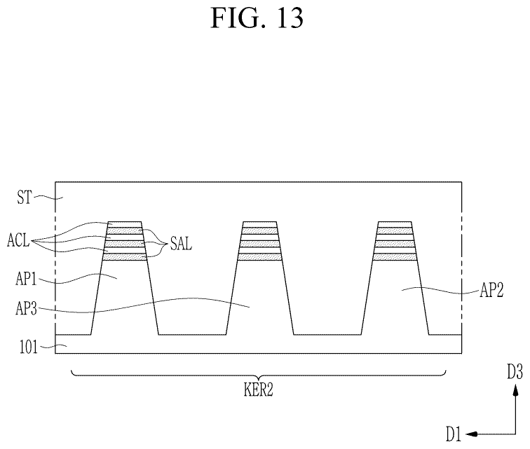

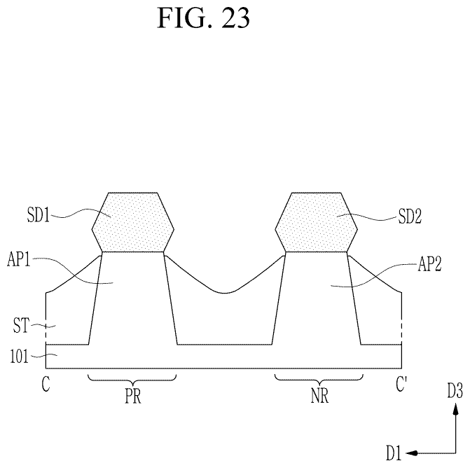

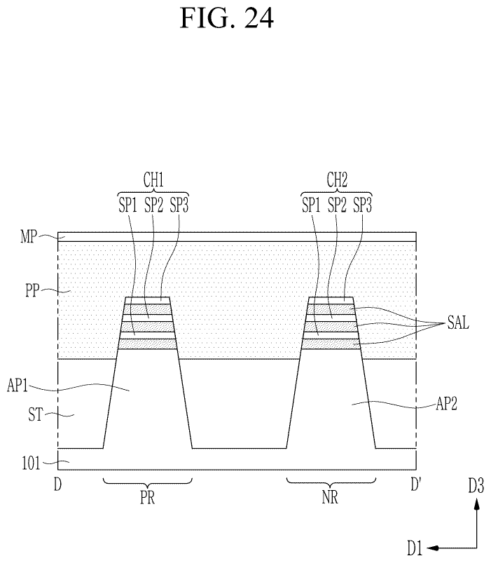

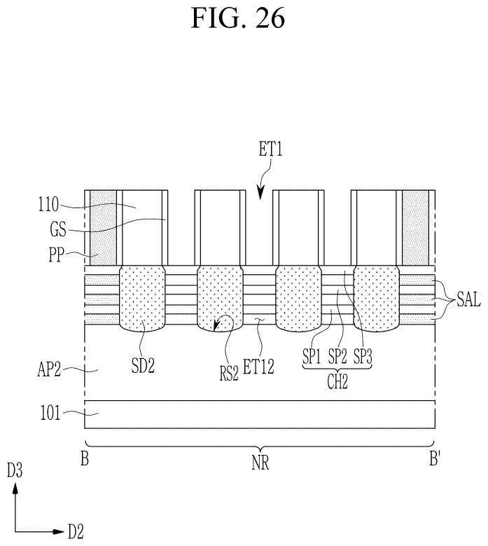

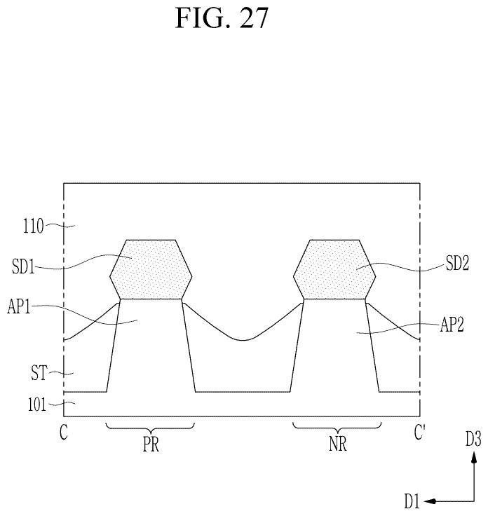

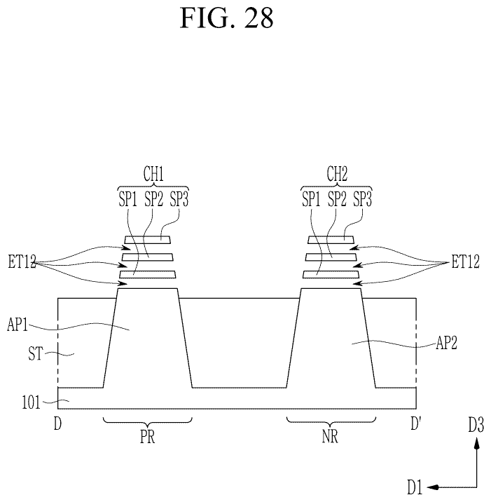

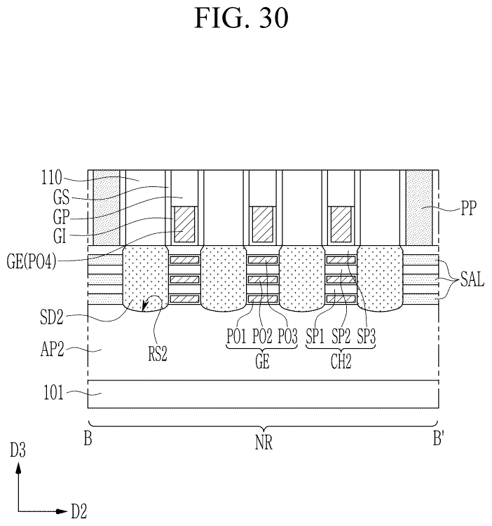

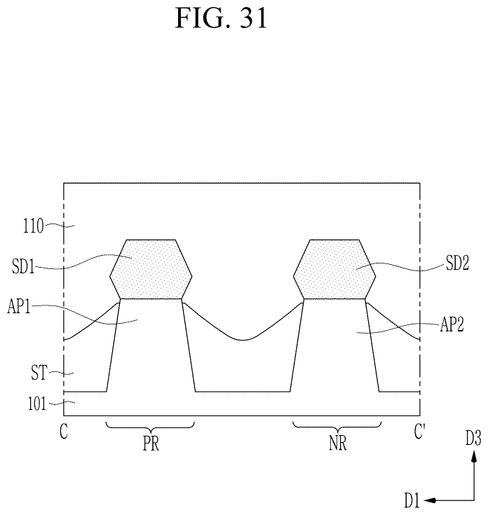

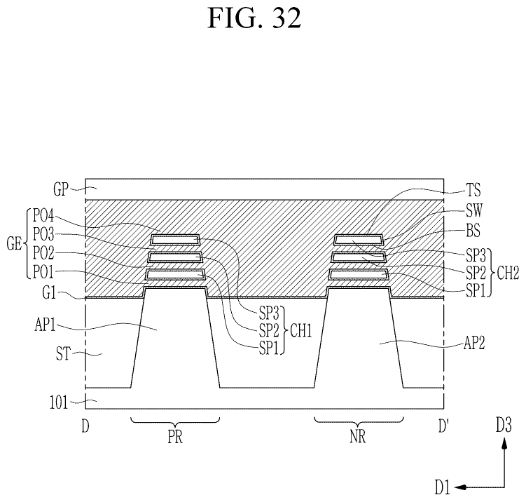

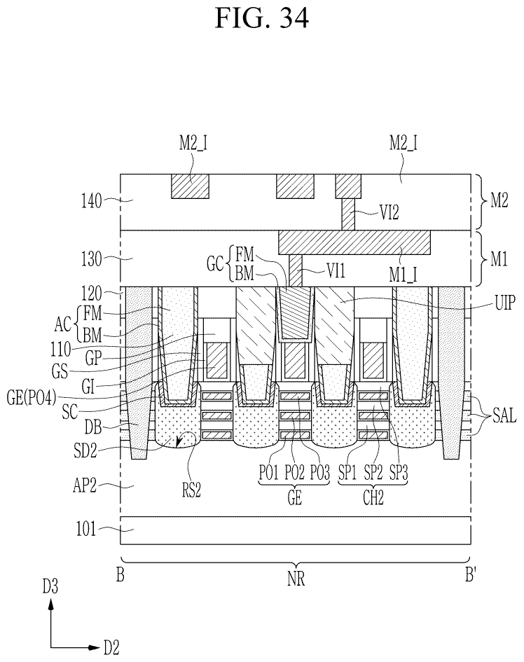

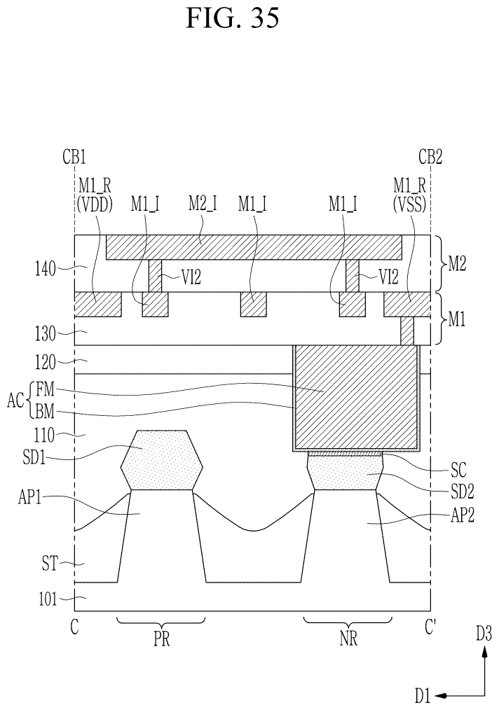

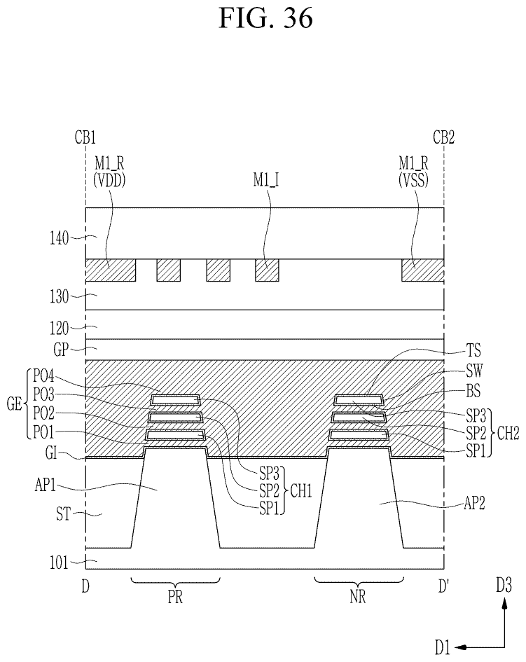

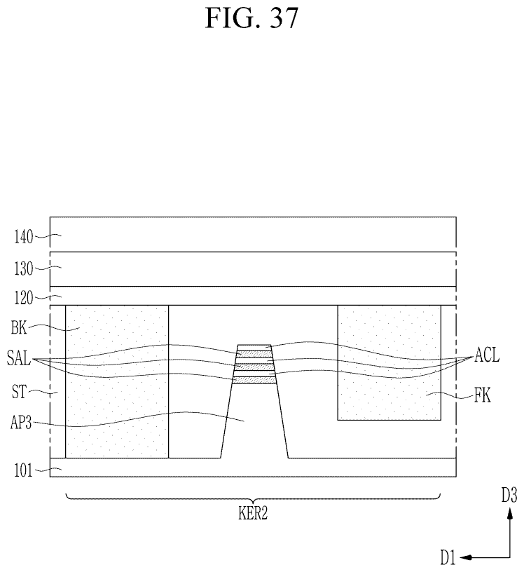

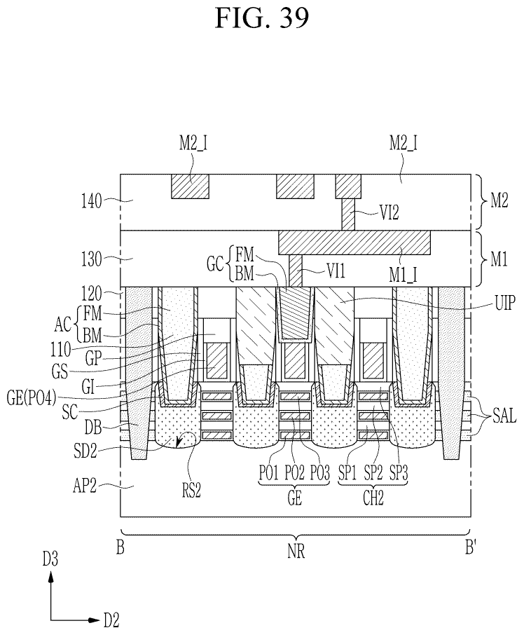

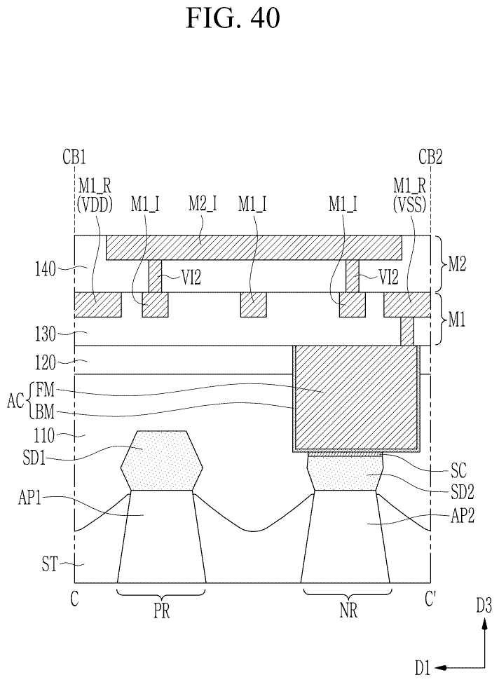

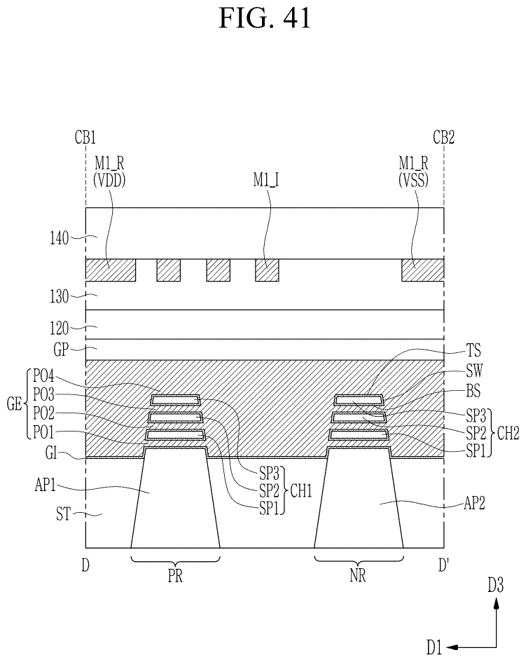

FIGS. 8 to 42 are cross-sectional views illustrating intermediate operations of a manufacturing method of a semiconductor device according to some embodiments.

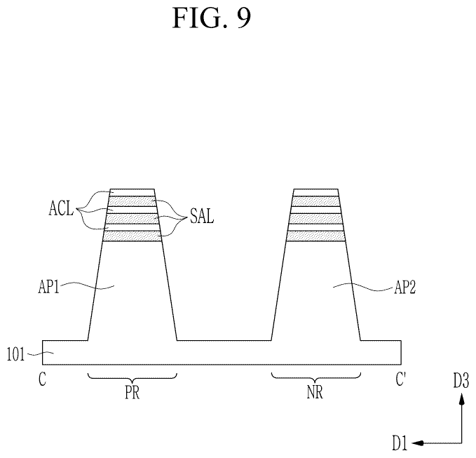

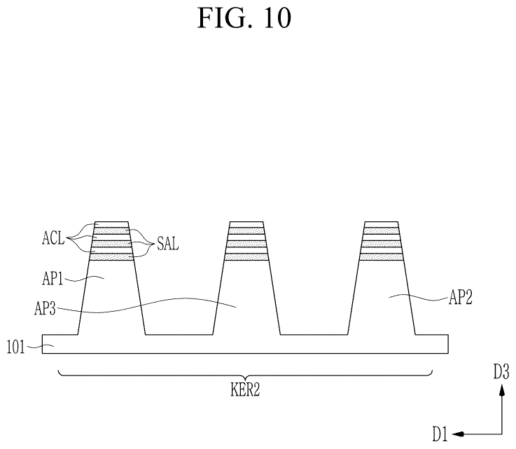

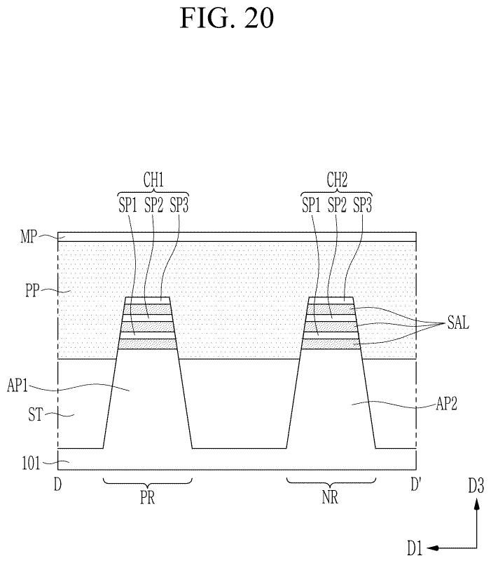

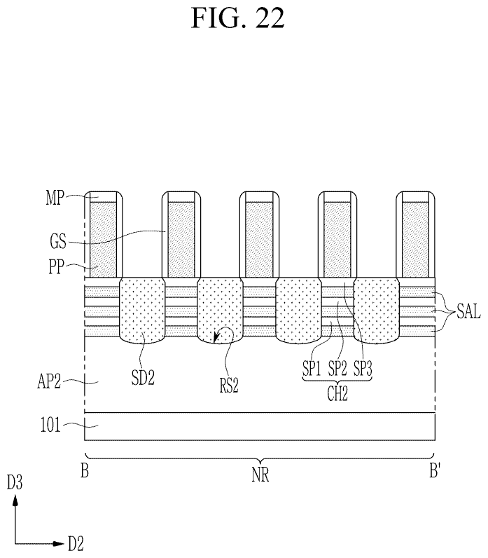

FIGS. 8, 11, 16, 18, 21, 25, 29, 33, and 38 are cross-sectional views taken along line A-A′ of FIG. 2. FIGS. 22, 26, 30, 34, and 39 are cross-sectional views taken along line B-B′ of FIG. 2. FIGS. 9, 12, 17, 19, 23, 27, 31, 35, and 40 are cross-sectional views taken along line C-C′ of FIG. 2. FIGS. 20, 24, 28, 32, 36, and 41 are cross-sectional views taken along line D-D′ of FIG. 2. FIGS. 10, 13, 14, 15, 37, and 42 are cross-sectional views showing the second overlay key region KER2 of FIG. 1.

Referring to FIGS. 8 to 10, the substrate 100 including the PMOSFET region PR and the NMOSFET region NR is formed.

First, the sacrificial layers SAL and the active layers ACL, which are alternately stacked, are formed on the substrate 100. The sacrificial layers SAL may include silicon (Si), germanium (Ge), or silicon-germanium (SiGe), and the active layers ACL may include silicon (Si), germanium (Ge), or silicon-germanium (SiGe). For example, the sacrificial layers SAL may include silicon-germanium (SiGe), and the active layers ACL may include silicon (Si). The concentration of germanium (Ge) in each of the sacrificial layers SAL may be 10 at % to 30 at %.

Mask patterns may be formed on the PMOSFET region PR of the substrate 100, the NMOSFET region NR, and the second overlay key region KER2, respectively. The mask pattern may have a line shape or a bar shape extending in the second direction D2.

By performing a patterning process using the mask patterns as an etching mask, a trench defining the first active pattern AP1, the second active pattern AP2, and the third active pattern AP3 may be formed, and a lower substrate 101 may be formed on a bottom surface of the trench. Accordingly, in the logic cell region CER, the first active pattern AP1 and the second active pattern AP2 may be formed in the PMOSFET region PR and the NMOSFET region NR, respectively, and the first active pattern AP1, the second active pattern AP2, and the third active pattern AP3 may be formed on the second overlay key region KER2.

Each of the first active pattern AP1, the second active pattern AP2, and the third active pattern AP3 may include the sacrificial layers SAL and the active layers ACL which are alternately stacked on an upper portion thereof.

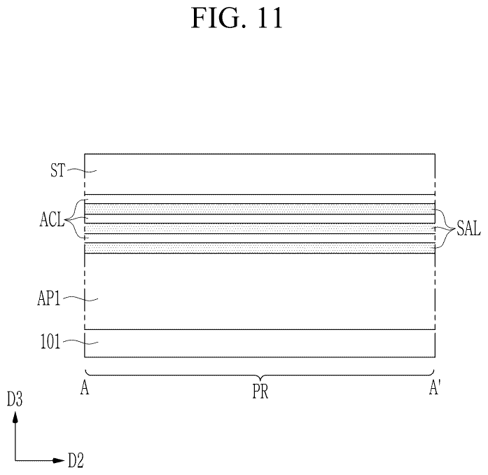

Referring to FIGS. 11 to 13, the device isolation layer ST at least partially filling the trench is formed on the lower substrate 101.

For example, the device isolation layer ST may be formed to cover all of the first active pattern AP1, the second active pattern AP2, and the third active pattern AP3.

The device isolation layer ST may include an insulating material, such as a silicon oxide layer.

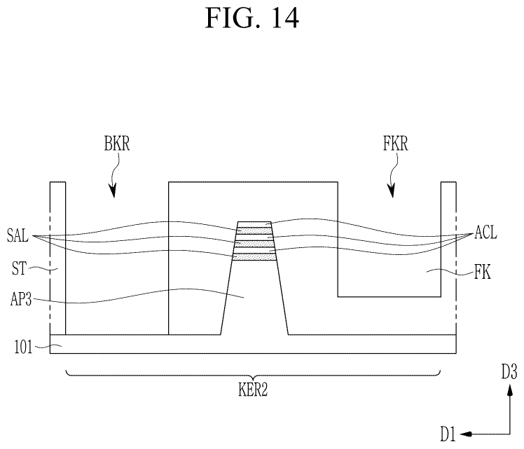

Referring to FIG. 14, a back-side key pattern recess BKR and a front-side key pattern recess FKR are formed in the second overlay key region KER2.

First, mask patterns may be formed on the first active pattern AP1 and the second active pattern AP2 of the logic cell region CER and the third active pattern AP3 of the second overlay key region KER2, respectively. The mask pattern may have a line shape or a bar shape extending in the second direction D2.

By performing a patterning process using the mask patterns as an etch mask, the first active pattern AP1 and the second active pattern AP2 of the overlay key region KER2 are removed, and the back-side key pattern recess BKR and the front-side key pattern recess FKR are formed in the second overlay key region KER2.

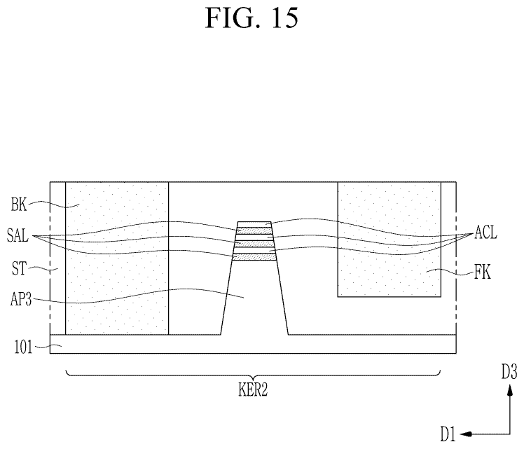

Referring to FIG. 15, the back-side key pattern BK and the front-side key pattern FK are formed in the second overlay key region KER2.

For example, the back-side key pattern BK and the front-side key pattern FK may be formed in the second overlay key region KER2 by filling the back-side key pattern recess BKR and the front-side key pattern recess FKR of the second overlay key region KER2 with an insulating material, such as a silicon oxide layer.

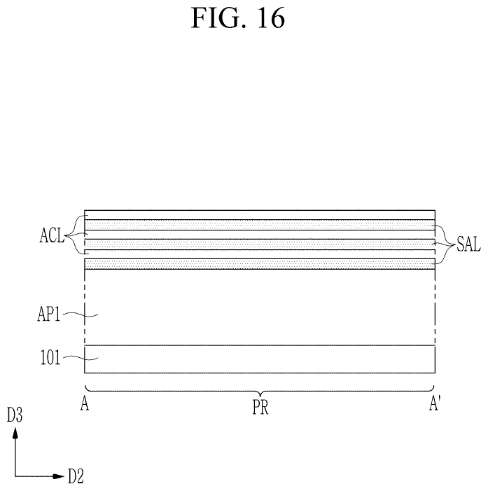

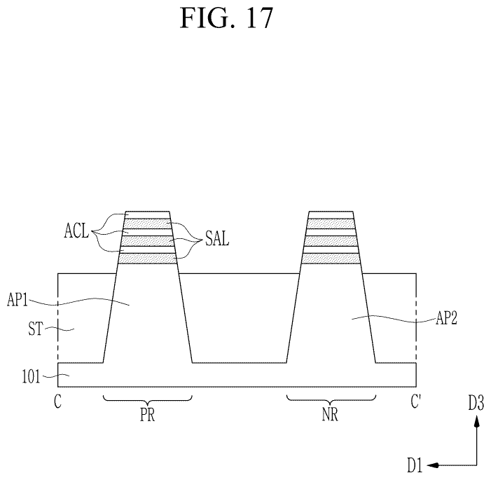

Referring to FIGS. 16 and 17, the sacrificial layers SAL on upper portions of the first active pattern AP1 and the second active pattern AP2 are exposed.

For example, mask patterns are formed on the first active pattern AP1 and the second active pattern AP2 of the logic cell region CER, a patterning process is performed using the mask patterns as an etching mask, and the device isolation layer ST is recessed until the sacrificial layers SAL are exposed.

Accordingly, an upper portion of each of the first active pattern AP1 and the second active pattern AP2 may be exposed above the device isolation layer ST. In other words, the upper portion of each of the first active pattern AP1 and the second active pattern AP2 may protrude in the third direction D3 of the device isolation layer ST.

At this time, a mask pattern is formed on the entire second overlay key region KER2, and the device isolation layer ST located in the second overlay key region KER2 may not be etched. In this case, as shown in FIG. 7, in the second overlay key region KER2, the device isolation layer ST of the substrate 100 may be formed to extend from the lower surface LS_100 of the substrate 100 to the upper surface US_100 in the third direction D3.

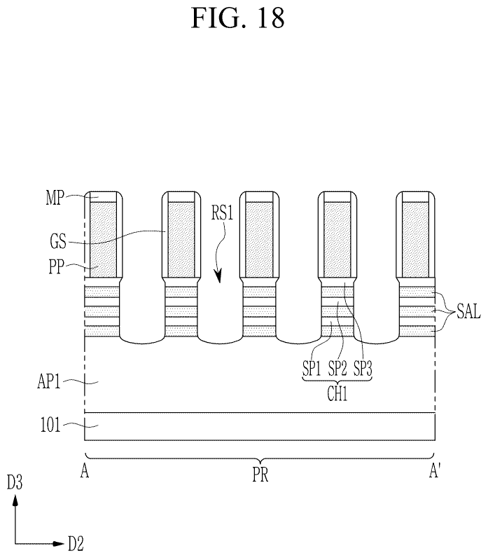

Referring to FIGS. 18 and 20, sacrificial patterns PP are formed across the first active pattern AP1 and the second active pattern AP2, and the first recesses RS1 and the second recesses RS2 are formed in the upper portions of the first active pattern AP1 and the second active pattern AP2, respectively.

First, the sacrificial pattern PP may be formed by forming a sacrificial layer on the entire surface of the lower substrate 101, forming a hard mask pattern MP on the sacrificial layer, and patterning on the sacrificial layer using the hard mask pattern MP as an etching mask.

For example, the sacrificial pattern PP may be formed in a line shape or a bar shape extending in the first direction D1. The sacrificial pattern PP may be disposed in the second direction D2 at a certain pitch. The sacrificial layer may include polysilicon.

At this time, the hard mask pattern MP may cover the entire surface of the second overlay key region KER2, and accordingly, the sacrificial layer is not formed in the second overlay key region KER2, and as shown in FIG. 15, the device isolation layer ST may cover the third active pattern AP3.

Next, a pair of gate spacers GS may be formed on both sidewalls of each of the sacrificial patterns PP.

For example, the gate spacer GS may be formed by conformally forming a gate spacer layer on the entire surface of the lower substrate 101, and anisotropically etching the gate spacer layer.

For example, the gate spacer layer may include SiCN, SiCON, SiN, or a combination thereof. In addition, the gate spacer layer may include a multi-layer including SiCN, SiCON, SiN, or a combination thereof.

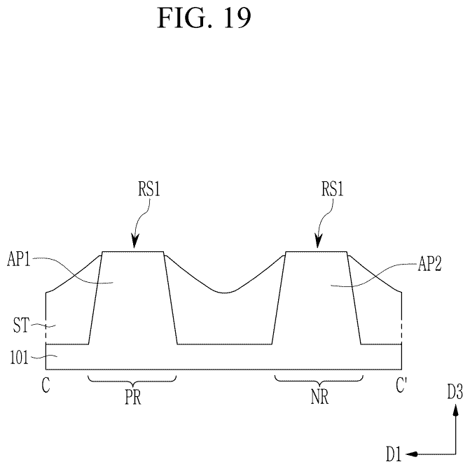

Next, the first recesses RS1 may be formed in the upper portion of the first active pattern AP1, and the second recesses RS2 may be formed in the upper portion of the second active pattern AP2. While the first and second recesses RS1 and RS2 are formed, an upper surface of the device isolation layer ST on both sides of each of the first and second active patterns AP1 and AP2 may be recessed (see FIG. 19).

For example, the first recesses RS1 may be formed by etching the upper portion of the first active pattern AP1 using the hard mask pattern MP and the gate spacer GS as an etching mask. The first recess RS1 may be formed between a pair of sacrificial patterns PP. The second recesses RS2 in the upper portion of the second active pattern AP2 may be formed in the same manner as the first recesses RS1.

As described above, the hard mask pattern MP may cover the entire surface of the second overlay key region KER2, and accordingly, recesses may not be formed in the third active pattern AP3 of the second overlay key region KER2.

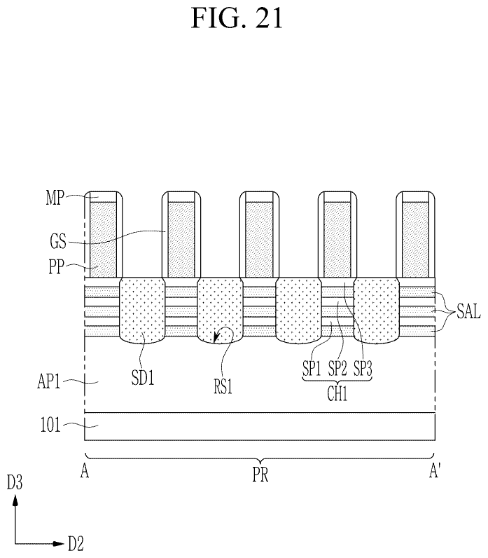

Referring to FIGS. 21 to 24, the first source/drain pattern SD1 is formed in the first recesses RS1, and the second source/drain pattern SD2 is formed in the second recesses RS2.

For example, a first semiconductor layer may be formed by performing a first selective epitaxial growth (SEG) process using an inner wall of the first recess RS1 as a seed layer. The first semiconductor layer may be grown using the first to third semiconductor patterns SP1, SP2, SP3 and the first active pattern AP1 exposed by the first recess RS1 as seeds. For example, the first SEG process may include a chemical vapor deposition (CVD) process or a molecular beam epitaxy (MBE) process.

The first semiconductor layer may include a semiconductor element (e.g., SiGe) having a lattice constant greater than a lattice constant of the semiconductor element of the first active pattern AP1. The first semiconductor layer may contain germanium (Ge) at a relatively low concentration. For another example, the first semiconductor layer may contain only silicon (Si) excluding germanium (Ge). The concentration of germanium (Ge) in the first semiconductor layer may be 0 at % to 10 at %.

A second semiconductor layer may be formed by performing a second SEG process on the first semiconductor layer. The second semiconductor layer may be formed in the first recess RS1. The second semiconductor layer may contain germanium (Ge) at a relatively high concentration. For example, the concentration of germanium (Ge) in the second semiconductor layer may be 30 at % to 70 at %.

The first semiconductor layer and the second semiconductor layer may constitute the first source/drain pattern SD1. During the first and second SEG processes, impurities may be injected in-situ. For another example, after the first source/drain pattern SD1 is formed, impurities may be injected into the first source/drain pattern SD1. The first source/drain pattern SD1 may be doped to have a first conductivity type (e.g., p-type).

Next, the second source/drain pattern SD2 may be formed by performing a SEG process using an inner wall of the second recess RS2 as a seed layer. For example, the second source/drain pattern SD2 may be grown using the first to third semiconductor patterns SP1, SP2, SP3 and the second active pattern AP2 exposed by the second recess RS2 as seeds.

For example, the second source/drain pattern SD2 may include the same semiconductor element (e.g., Si) as the second active pattern AP2. The second source/drain pattern SD2 may be doped to have a second conductivity type (e.g., n-type).

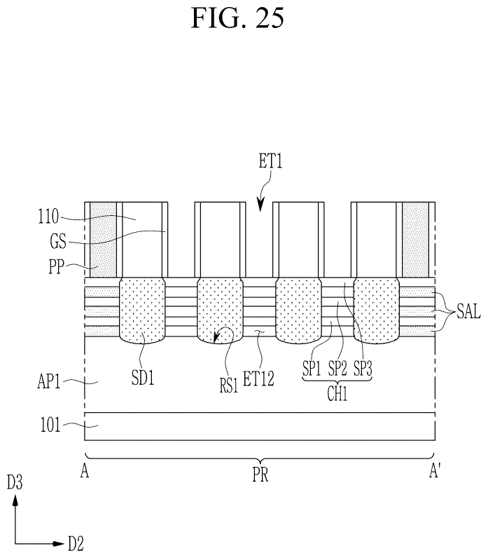

Referring to FIGS. 25 to 28, after the first interlayer insulating layer 110 is formed, the sacrificial pattern PP is removed, and the exposed sacrificial layers SAL are removed.

First, the first interlayer insulating layer 110 covering the first and second source/drain patterns SD1 and SD2, the hard mask pattern MP, and the gate spacer GS is formed. For example, the first interlayer insulating layer 110 may include a silicon oxide layer.

Next, the first interlayer insulating layer 110 may be planarized until an upper surface of the sacrificial pattern PP is exposed. Planarization of the first interlayer insulating layer 110 may be performed using an etch back or chemical mechanical polishing (CMP) process. During a planarization process, the hard mask pattern MP may be completely removed. As a result, an upper surface of the first interlayer insulating layer 110 may be located at substantially the same level as the upper surface of the sacrificial pattern PP and the upper surface of the gate spacer GS in the third direction D3.

The exposed sacrificial pattern PP may be selectively removed. The sacrificial pattern PP is removed, and thus, first empty spaces ET1 exposing the first and second active patterns AP1 and AP2 may be formed.

Meanwhile, some of the sacrificial patterns PP may not be removed. For example, the sacrificial patterns PP located at a cell boundary may not be removed. For example, a mask pattern is formed on the sacrificial patterns PP that need not to be removed, and thus, the sacrificial patterns PP may remain without being removed. The sacrificial patterns PP are removed, and thus, the sacrificial layers SAL of each of the first and second active patterns AP1 and AP2 may be exposed through the first empty space ET1.

Next, the sacrificial layers SAL exposed through the first empty space ET1 may be selectively removed.

For example, by performing an etching process to selectively etch the sacrificial layers SAL, only the sacrificial layers SAL may be removed while the first to third semiconductor patterns SP1, SP2, and SP3 remain generally intact as they are.

For example, the etching process may have a high etch rate with respect to silicon-germanium having a relatively high concentration of germanium. For example, the etching process may have a high etch rate with respect to silicon-germanium having a concentration of germanium greater than 10 at %.

During the etching process, the sacrificial layers SAL on the PMOSFET region PR and the NMOSFET region NR may be removed. The etching process may be wet etching. An etching material used in the etching process may relatively quickly remove the sacrificial layer SAL with a relatively high concentration of germanium.

The sacrificial layers SAL are selectively removed, and thus, only the first to third semiconductor patterns SP1, SP2, and SP3 may remain on each of the first and second active patterns AP1 and AP2. Second empty spaces ET2 may be formed through regions from which the sacrificial layers SAL have been removed. The second empty spaces ET2 may be located between the first to third semiconductor patterns SP1, SP2, and SP3.

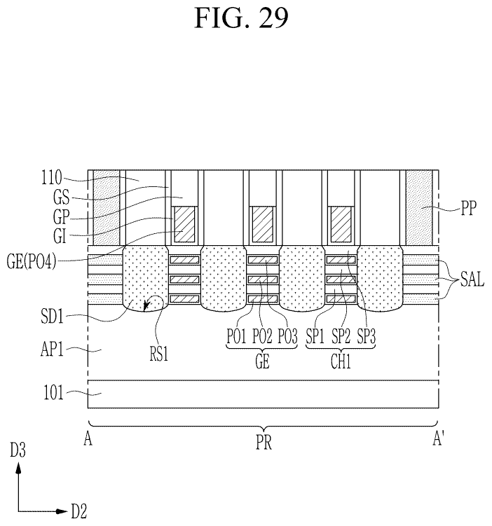

Referring to FIGS. 29 to 32, the gate pattern GE is formed in the first and second empty spaces ET1 and ET2.

First, the gate insulating layer GI is conformally formed in the first and second empty spaces ET1 and ET2. Thereafter, the gate pattern GE may be formed on the gate insulating layer GI. The gate pattern GE may be formed to be in and at least partially fill the first and second empty spaces ET1 and ET2.

For example, the gate pattern GE may include the first to third portions PO1, PO2, and PO3 that at least partially fill the second empty spaces ET2. The gate pattern GE may further include the fourth portion PO4 that fills the first empty space ET1.

Next, the gate capping pattern GP covering the gate pattern GE may be formed on the gate pattern GE.

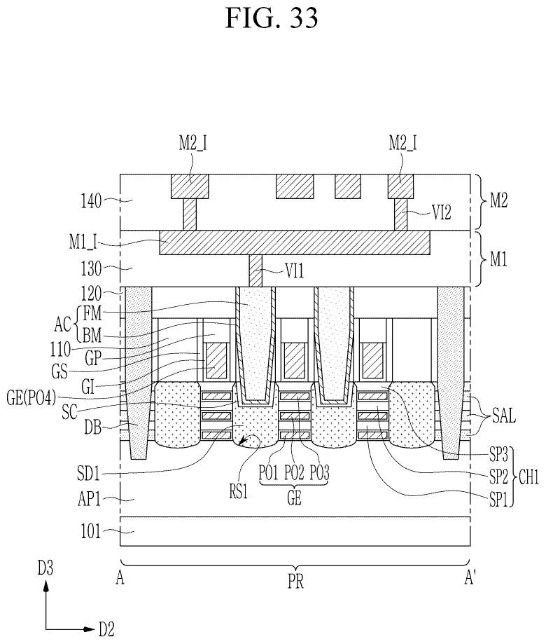

Referring to FIGS. 33 to 37, the upper active contact AC, the upper gate contact GC, and the first upper interlayer insulating layer 130 are formed.

First, the second interlayer insulating layer 120 may be formed on the first interlayer insulating layer 110. The second interlayer insulating layer 120 may include a silicon oxide layer.

The upper active contact AC penetrating or extending into the first and second interlayer insulating layers 110 and 120 and electrically connected to the first and second source/drain patterns SD1 and SD2 may be formed.

In addition, the upper gate contact GC penetrating or extending into the second interlayer insulating layer 120 and the gate capping pattern GP and electrically connected to the gate pattern GE may be formed.

At this time, when the front-side key pattern FK exposed on the upper surface US_100 of the substrate 100 is used, the upper gate contact GC may be aligned with the gate pattern GE when formed, and the upper active contact AC may be aligned with the first and second source/drain patterns SD1 and SD2 when formed, when the upper active contact AC is formed after the upper gate contact GC is first formed, the upper gate contact GC and the upper active contact AC may be aligned, or when the upper gate contact GC is formed after the upper active contact AC is first formed, the upper active contact AC and the upper gate contact GC may be aligned.

For example, a contact hole penetrating or extending into the first and second interlayer insulating layers 110 and 120 and exposing the first and second source/drain patterns SD1 and SD2 may be formed. Next, the upper active contact AC at least partially filling the contact hole and electrically connected to the first and second source/drain patterns SD1 and SD2 is formed. For example, the barrier pattern BM and the conductive pattern FM may be sequentially formed within the contact hole.

Next, the upper gate contact GC is formed within the second interlayer insulating layer 120 and the gate capping pattern GP.

First, a contact hole penetrating or extending into the second interlayer insulating layer 120 and the gate capping pattern GP and exposing the fourth portion PO4 of the gate pattern GE may be formed.

Next, the upper gate contact GC at least partially filling the contact hole and electrically connected to the fourth portion PO4 of the gate pattern GE is formed. For example, the barrier pattern BM and the conductive pattern FM may be sequentially formed within the contact hole.

In addition, a pair of separation structures DB may be formed on both sides of the logic cell LC. The separation structure DB may penetrate or extend into the second interlayer insulating layer 120, the remaining sacrificial pattern PP, and the upper portion of the first or second active pattern AP1 or AP2 below the sacrificial pattern PP.

The separation structure DB may include an insulating material, such as a silicon oxide layer or a silicon nitride layer.

Next, the upper interlayer insulating layer 130 including the first upper metal layer M1 electrically connected to the upper active contact AC and the upper gate contact GC is formed on the upper surface of each of the second interlayer insulating layer 120 and the gate capping pattern GP.

In addition, the second upper interlayer insulating layer 140 including the second upper metal layer M2 electrically connected to the first upper metal layer M1 is formed on the upper surface of the first upper interlayer insulating layer 130.

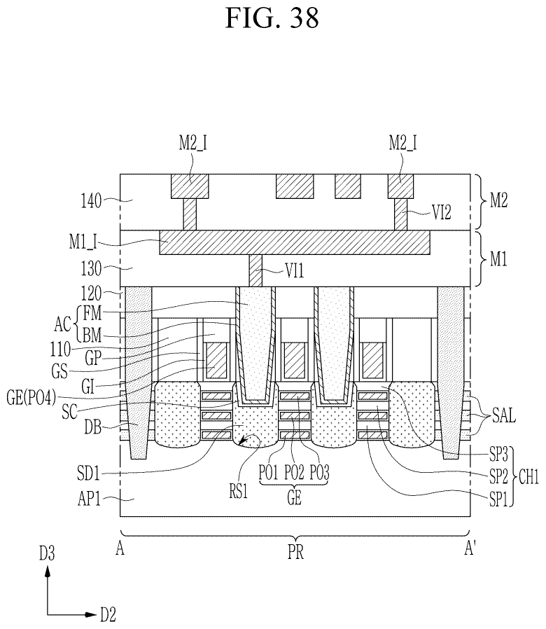

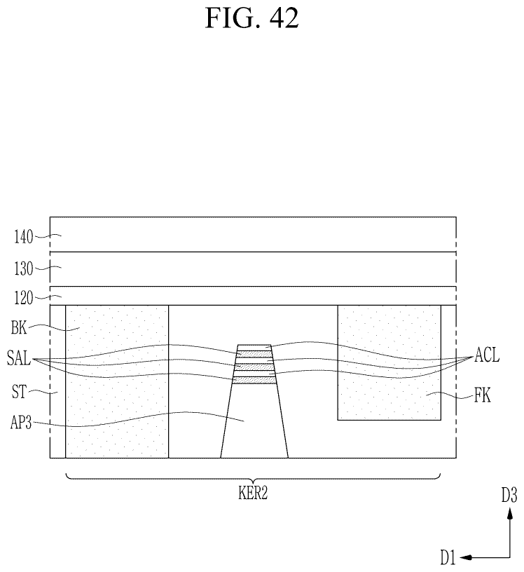

As shown in FIGS. 38 and 42, the lower substrate 101 is removed.

First, the semiconductor device may be rotated. However, FIGS. 38 and 42 show a state in which the semiconductor device is not rotated.

For example, the rotated semiconductor device may be disposed on a carrier substrate (not shown). At this time, an upper surface of the semiconductor device may be located to face the carrier substrate and then attached to the carrier substrate. That is, the second upper interlayer insulating layer 140 located on the upper surface of the semiconductor device may be attached onto the carrier substrate. An adhesive member (not shown) may be disposed between the second upper interlayer insulating layer 140 and the carrier substrate.

The carrier substrate may have substantially the same area as or a larger area than the semiconductor device. The carrier substrate may be, for example, a semiconductor wafer, a ceramic substrate, or a glass substrate. The adhesive member may be in the form of a film.

The adhesive member may include a base film and an adhesive layer attached to both sides of the base film. The base film may be, for example, a polyethylene-based film, such as polyethylene terephthalate (PET) or polyethylene-2,6-naphthalenedicarboxylate (PEN), or a polyolefin-based film. The base film may be formed by coding silicone or Teflon on a polyethylene-based film or a polyolefin-based film. The adhesive layer may include, for example, acrylic polymer resin, epoxy resin, or a mixture thereof.

Next, the lower substrate 101 may be removed by performing an etching process. The etching process may be performed, for example, by a wet etching method, but is not limited thereto.

The lower substrate 101 is removed, and thus, the lower surface LS_BK of the back-side key pattern BK may penetrate or extend into the lower surface LS_100 of the substrate 100 and be exposed.

Accordingly, when the back-side key pattern BK exposed on the lower surface LS_100 of the substrate 100 is used, the lower gate contact GCb may be aligned with the gate pattern GE located on the front surface when formed, and the lower active contact ACb may be aligned with the first and second source/drain patterns SD1 and SD2 located on the front surface, when the lower active contact ACb is formed after the lower gate contact GCb is first formed, the lower gate contact GCb and the lower active contact ACb may be aligned, or when the lower gate contact GCb is formed after the lower active contact ACb is first formed, the lower active contact ACb and the lower gate contact GCb may be aligned. Accordingly, when a BSPDN structure is applied, alignment errors between the lower active contact ACb and the lower gate contact GCb located on the back surface and the first and second source/drain patterns SD1 and SD2 and the gate pattern GE located on the front surface may be reduced.

For example, a patterning process may be performed to remove a part of the first active pattern AP1 and form a contact hole exposing the first source/drain pattern SD1. At this time, the contact hole may penetrate or extend into the first active pattern AP1. In other words, a side surface of the contact hole may be at least partially surrounded by the first active pattern AP1. However, embodiments of the present disclosure are not limited thereto, and the contact hole may expose the second source/drain pattern SD2 by removing a part of the second active pattern AP2.

Next, the lower active contact ACb at least partially filling the contact hole and electrically connected to the first source/drain pattern SD1 is formed. For example, the barrier pattern BM and the conductive pattern FM may be sequentially formed within the contact hole. However, embodiments of the present disclosure are not limited thereto, and the lower active contact ACb may be electrically connected to the second source/drain pattern SD2.

Next, a patterning process may be performed to remove a part of the first active pattern AP1 and form a contact hole exposing the first portion PO1 of the gate pattern GE. At this time, the contact hole may penetrate or extend into the first active pattern AP1. In other words, the side surface of the contact hole may be at least partially surrounded by the first active pattern AP1. However, embodiments of the present disclosure are not limited thereto, and the contact hole may remove a part of the second active pattern AP2 and expose the first portion PO1 of the gate pattern GE.

Next, the lower gate contact GCb at least partially filling the contact hole and electrically connected to the first portion PO1 of the gate pattern GE is formed. For example, the barrier pattern BM and the conductive pattern FM may be sequentially formed within the contact hole.

In the above, a case where the lower active contact ACb and the lower gate contact GCb are formed in separate processes has been described, but embodiments of the present disclosure are not limited thereto, and the lower active contact ACb and the lower gate contact GCb may be formed simultaneously, and the lower gate contact GCb may be formed first, and then the lower active contact ACb may be formed.

Next, the first lower interlayer insulating layer 130b including the first lower metal layer Mlb electrically connected to the lower active contact ACb and the lower gate contact GCb is formed on a lower surface of the device isolation layer ST and the first and second active patterns AP1 and AP2.

In addition, the second lower interlayer insulating layer 140b including the second lower metal layer M2b electrically connected to the first lower metal layer Mlb is formed on a lower surface of the first lower interlayer insulating layer 130b.

Although the embodiments of the present disclosure have been described in detail above, the scope of the present disclosure is not limited thereto, and various modifications and improvements made by those of ordinary skill in the field to which the present disclosure pertains also belong to the scope of the present disclosure.

### DESCRIPTION OF SYMBOLS

CER: logic cell region
KER1, KER2, KER3: first to third overlay key regions
100: substrate
AP1, AP2, AP3: first to third active patterns
CH1, CH2: first and second channel pattern
GE: gate pattern
SD1, SD2: first and second source/drain patterns
110: first interlayer insulating layer
120: second interlayer insulating layer
AC: upper active contact GC: upper gate contact
ACb: lower active contact GCb: lower gate contact
130: first upper interlayer insulating layer
140: second upper interlayer insulating layer
130b: first lower interlayer insulating layer
140b: second lower interlayer insulating layer
M1: first upper metal layerM2: second upper metal layer
Mlb: first lower metal layerM2b: second lower metal layer
BK: back-side key patternFK: front-side key pattern

What is claimed is:

1. A semiconductor device comprising:
a substrate comprising a logic cell region comprising active patterns spaced apart in a first direction and extending in a second direction different from the first direction, and an overlay key region comprising a back-side key pattern and a front-side key pattern;
source/drain patterns on the active patterns of the logic cell region and spaced apart in the second direction;
a channel pattern between the source/drain patterns; and
a gate pattern extending in the first direction, crossing between the source/drain patterns, and surrounding at least a part of the channel pattern,
wherein the substrate has an upper surface and a lower surface facing each other in a third direction different from the first direction and the second direction, and the back-side key pattern of the overlay key region extends into the lower surface of the substrate.

2. The semiconductor device of claim 1, wherein:
a lower surface of the back-side key pattern and the lower surface of the substrate are generally coplanar.

3. The semiconductor device of claim 1, wherein:
the back-side key pattern extends in the third direction from the lower surface of the substrate to the upper surface.

4. The semiconductor device of claim 1, wherein:
the front-side key pattern is spaced apart from the lower surface of the substrate.

5. The semiconductor device of claim 1, wherein:
a lower surface of the back-side key pattern is located closer to the lower surface of the substrate than a lower surface of the front-side key pattern.

6. The semiconductor device of claim 1, wherein:
an upper surface of the back-side key pattern extends into the upper surface of the substrate, and
an upper surface of the front-side key pattern extends into the upper surface of the substrate.

7. The semiconductor device of claim 6, wherein:
the upper surface of the back-side key pattern and the upper surface of the substrate are located at a same level in the third direction, and
the upper surface of the front-side key pattern and the upper surface of the substrate are generally coplanar.

8. The semiconductor device of claim 1, wherein:
a length of the back-side key pattern in the third direction is greater a length of the front-side key pattern in the third direction.

9. The semiconductor device of claim 1, further comprising:
an upper active contact above the source/drain patterns and connected to the source/drain patterns in the third direction with the lower surface of the substrate being a base reference plane; and
an upper gate contact above the gate pattern in the third direction with the lower surface of the substrate being the base reference plane and connected to the gate pattern.

10. The semiconductor device of claim 9, further comprising:
a first upper interlayer insulating layer above the upper active contact and the upper gate contact in the third direction with the lower surface of the substrate being the base reference plane and including a first upper metal layer.

11. The semiconductor device of claim 1, further comprising:
an interlayer insulating layer on the substrate,
wherein an upper surface of the back-side key pattern contacts a lower surface of the interlayer insulating layer, and
an upper surface of the front-side key pattern contacts the lower surface of the interlayer insulating layer.

12. The semiconductor device of claim 1, further comprising:
a lower active contact below the source/drain patterns, extending into the active patterns, and electrically connected to the source/drain patterns; and
a lower gate contact below the gate pattern, extending into the active patterns, and electrically connected to the gate pattern.

13. The semiconductor device of claim 1, further comprising:
a first lower interlayer insulating layer below the lower active contact and the lower gate contact in the third direction with the lower surface of the substrate being a base reference plane and including a first lower metal layer.

14. The semiconductor device of claim 13, wherein:
a lower surface of the back-side key pattern contacts an upper surface of the first lower interlayer insulating layer.

15. The semiconductor device of claim 1, wherein:
the back-side key pattern includes silicon oxide, and
the front-side key pattern includes silicon oxide.

16. A semiconductor device comprising:
a substrate comprising a logic cell region comprising active patterns spaced apart in a first direction and extending in a second direction different from the first direction, and an overlay key region comprising a front-side key pattern and a back-side key pattern, the substrate having an upper surface and a lower surface facing each other in a third direction different from the first direction and the second direction;
source/drain patterns on the active patterns of the logic cell region and spaced apart in the second direction;
a channel pattern located between the source/drain patterns;
a gate pattern extending in the first direction, crossing between the source/drain patterns, and surrounding at least a part of the channel pattern;
a lower active contact below the source/drain patterns in the third direction with the lower surface of the substrate being a base reference plane, extending into the active patterns, and electrically connected to the source/drain patterns, and a lower gate contact below the gate pattern in the third direction with the lower surface of the substrate being the base reference plane, extending into the active patterns, and electrically connected to the gate pattern; and
a first lower interlayer insulating layer below the lower active contact and the lower gate contact in the third direction with the lower surface of the substrate being the base reference plane and comprising a first lower metal layer,
wherein a lower surface of the back-side key pattern of the overlay key region contacts the first lower interlayer insulating layer.

17. The semiconductor device of claim 16, further comprising:
an upper active contact located above the source/drain patterns in the third direction with the lower surface of the substrate being the base reference plane and connected to the source/drain patterns;
an upper gate contact located above the gate pattern in the third direction with the lower surface of the substrate being the base reference plane and connected to the gate pattern; and
a first upper interlayer insulating layer above the upper active contact and the upper gate contact in the third direction with the lower surface of the substrate being the base reference plane and including a first upper metal layer.

18. The semiconductor device of claim 17, wherein:
an upper surface of the back-side key pattern contacts a lower surface of the first upper interlayer insulating layer, and
an upper surface of the front-side key pattern contacts the lower surface of the first upper interlayer insulating layer.

19. A semiconductor device comprising:
a substrate comprising active patterns spaced apart in a first direction and extending in a second direction different from the first direction, a device isolation pattern between the active patterns in the first direction, and a back-side key pattern and a front-side key pattern on the device isolation pattern; and
sacrificial layers and active layers on the active patterns and alternately stacked in a third direction different from the first direction and the second direction,
wherein the back-side key pattern extends into a lower surface of the device isolation pattern, and
wherein the front-side key pattern extends into an upper surface of the device isolation pattern, and is spaced apart from a lower surface of the substrate.

20. The semiconductor device of claim 19, wherein:
a lower surface of the front-side key pattern is at a lower level in the third direction than the sacrificial layers with the lower surface of the substrate being a base reference plane.
